(19) United States
(12) Patent Application Publication
(10) Pub. No.: US 2025/0040132 A1
(43) Pub. Date: Jan. 30, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Taeseop Choi, Suwon-si (KR); Byunghoon Kim, Suwon-si (KR); Junho Kim, Suwon-si (KR); Youngwook Park, Suwon-si (KR); Jiho Park, Suwon-si (KR); Jungwoo Lee, Suwon-si (KR); Jihyun Hwang, Suwon-si (KR); Minho Choi, Suwon-si (KR)

(21) Appl. No.: 18/626,728

(22) Filed: Apr. 4, 2024

(30) Foreign Application Priority Data
Jul. 27, 2023 (KR) 10-2023-0098361

(51) Int. Cl. H10B 12/00

(52) U.S. Cl. CPC H10B 12/50; H10B 12/09; H10B 12/34

(57) ABSTRACT

A semiconductor device includes a substrate including a cell region, a core region, and a boundary region between the cell region and the core region, where the substrate includes at least one first active pattern in the cell region and a second active pattern in the core region; a first trench defined by the at least one first active pattern; and a second trench defined by the second active pattern, where an inner sidewall of the first trench defines first recesses that extend into the at least one first active pattern, an inner sidewall of the second trench defines second recesses that extend into the second active pattern, a distance between two adjacent first recesses from among the first recesses in the vertical direction corresponds to a first height, a distance between two adjacent second recesses from among the second recesses in the vertical direction corresponds to a second height.

### CROSS-REFERENCE TO RELATED APPLICATION

This application is based on and claims priority under 35 U.S.C. § 119 to Korean Patent Application No. 10-2023-0098361, filed on Jul. 27, 2023, in the Korean Intellectual Property Office, the disclosure of which is incorporated by reference herein in its entirety.

### TECHNICAL FIELD

The present disclosure relates to a semiconductor device and a method of manufacturing the same, and more particularly, to a semiconductor memory device having increased reliability and a method of manufacturing the same.

### BACKGROUND

Semiconductor devices have been highlighted as an important factor in the electronics industry due to their compactness, multifunctionalization, and/or low manufacturing cost. Among semiconductor devices, data storage devices may store logical data. With the development of the electronics industry, data storage devices are becoming highly integrated. Accordingly, the dimensions of elements of data storage devices are decreasing.

With the high integration of data storage devices, there is also a demand for high reliability of data storage devices. However, because of the high integration of data storage devices, the reliability of data storage devices may decrease.

### SUMMARY

The present disclosure provides a semiconductor memory device having improved electrical characteristics and increased reliability.

The present disclosure also provides a method of manufacturing a semiconductor memory device having improved electrical characteristics and increased reliability.

According to an aspect of the present disclosure, there is provided a semiconductor device including a substrate that includes a cell region, a core region, and a boundary region between the cell region and the core region, where the substrate includes at least one first active pattern in the cell region and a second active pattern in the core region; a first trench defined by the at least one first active pattern; and a second trench defined by the second active pattern, where an inner sidewall of the first trench defines first recesses that extend into the at least one first active pattern, where the first recesses are spaced apart from each other in a vertical direction that intersects a top surface of the substrate, an inner sidewall of the second trench defines second recesses that extend into the second active pattern, where the second recesses are spaced apart from each other in the vertical direction, a distance between two adjacent first recesses from among the first recesses in the vertical direction corresponds to a first height, a distance between two adjacent second recesses from among the second recesses in the vertical direction corresponds to a second height, and the second height is greater than the first height.

According to another aspect of the present disclosure, there is provided a semiconductor device including a substrate including a cell region, a core region, and a boundary region between the cell region and the core region, where the substrate includes first active patterns spaced apart in a first horizontal direction and a second horizontal direction in the cell region, where the first horizontal direction is parallel with a top surface of the substrate, and where the second horizontal direction is parallel with the top surface of the substrate and perpendicular to the first horizontal direction; a first trench and a second trench that are defined by the first active patterns; and an isolation film in the first trench and the second trench, where each of the first active patterns includes a long axis in a third horizontal direction that is parallel with the top surface of the substrate and intersects the first horizontal direction and the second horizontal direction, the first trench is between a first adjacent pair of first active patterns in the second horizontal direction from among the first active patterns, the second trench is between a second adjacent pair of first active patterns in the third horizontal direction from among the first active patterns, a width of the second trench is greater than a width of the first trench, and a bottom of the first trench and a bottom of the second trench extend from the substrate by a substantially equal distance.

According to a further aspect of the present disclosure, there is provided a semiconductor device including a cell region, a core region, and a boundary region between the cell region and the core region, where the substrate includes a first active pattern in the cell region and a second active pattern in the core region, where the first active pattern includes a long axis in a first horizontal direction, a first source/drain region, and a second source/drain region that is spaced apart from the first source/drain region in the first horizontal direction; a first trench that is defined by the first active pattern, where an inner sidewall of the first trench includes first recesses that extend into the first active pattern; a second trench that is defined by the second active pattern, where an inner sidewall of the second trench includes second recesses that extend into the second active pattern; an isolation film in the first trench and the second trench; a gate electrode in a groove between the first and second source/drain regions of the first active pattern, where the gate electrode extends in a second horizontal direction; a line structure that extends on the first active pattern in a third horizontal direction that intersects the second horizontal direction, where the line structure extends from the cell region to the boundary region and includes a first conductive pattern, a bit line on the first conductive pattern, and a first barrier pattern between the bit line and the first conductive pattern, and where the first conductive pattern is electrically connected to the first source/drain region; a core gate structure on the second active pattern, where the core gate structure includes a second conductive pattern corresponding to the first conductive pattern, a second barrier pattern corresponding to the first barrier pattern, and a core gate electrode corresponding to the bit line; and a sidewall spacer on a sidewall of the core gate structure, where a distance between two adjacent first recesses from among the first recesses in a vertical direction that intersects a top surface of the substrate is less than a distance between two adjacent second recesses from among the second recesses in the vertical direction.

### BRIEF DESCRIPTION OF THE DRAWINGS

Embodiments will be more clearly understood from the following detailed description taken in conjunction with the accompanying drawings in which:

FIG. 1 is a plan view of a semiconductor device according to embodiments of the present disclosure;

FIG. 2 is an enlarged plan view of a region PP in the boundary between a cell region and a core region in FIG. 1;

FIG. 3A is a cross-sectional view taken along line A-A′ in FIG. 2, FIG. 3B is a cross-sectional view taken along line B-B′ in FIG. 2, FIG. 3C is a cross-sectional view taken along line C-C′ in FIG. 2, FIG. 3D is a cross-sectional view taken along line D-D′ in FIG. 2, and FIG. 3E is a cross-sectional view taken along line E-E′ in FIG. 2;

FIG. 4A is an enlarged view of a region PP1 in FIG. 3B, FIG. 4B is an enlarged view of a region PP2 in FIG. 3D, and FIG. 4C is an enlarged view of a region PP3 in FIG. 3E according to embodiments of the present disclosure;

FIG. 4D is an enlarged view of the region PP1 in FIGS. 3B and 4E is an enlarged view of the region PP3 in FIG. 3E according to some embodiments of the present disclosure;

FIG. 4F is an enlarged view of the region PP1 in FIG. 3B, FIG. 4G is an enlarged plan view of the region PP2 in FIGS. 3D, and 4H is an enlarged view of the region PP3 in FIG. 3E according to some embodiments of the present disclosure;

FIGS. 5A to 19C are diagrams illustrating a method of manufacturing a semiconductor device according to embodiments of the present disclosure, wherein FIGS. 5A, 6A, 7A, 8A, 9A, 10A, 11A, 12A, 13A, 14A, 15A, 16A, 17A, 18A, and 19A are cross-sectional views taken along line A-A′ in FIG. 2, FIGS. 5B, 6B, 7B, 8B, 9B, 10B, 11B, 12B, 13B, 14B, 15B, 16B, 17B, 18B, and 19B are cross-sectional views taken along line B-B′ in FIG. 2, FIGS. 5C, 6C, 7C, 8C, 9C, 10C, 11C, 12C, 13C, 14C, 15C, 16C, 17C, 18C, and 19C are cross-sectional views taken along line C-C′ in FIG. 2, FIGS. 5D, 6D, 7D, 8D, 9D, 10D, 11D, 12D, 13D, 14D, 15D, 16D, 17D, and 18D are cross-sectional views taken along line D-D′ in FIG. 2, and FIGS. 5E, 6E, 7E, 8E, 9E, 10E, 11E, 12E, 13E, 14E, 15E, 16E, 17E, and 18E are cross-sectional views taken along line E-E′ in FIG. 2; and

FIGS. 20A to 22E are diagrams illustrating a method of manufacturing a semiconductor device according to some embodiments of the present disclosure, wherein FIGS. 20A, 21A, and 22A are cross-sectional views taken along line A-A′ in FIG. 2, FIGS. 20B, 21B, and 22B are cross-sectional views taken along line B-B′ in FIG. 2, FIGS. 20C, 21C, and 22C are cross-sectional views taken along line C-C′ in FIG. 2, FIGS. 20D, 21D, and 22D are cross-sectional views taken along line D-D′ in FIG. 2, and FIGS. 20E, 21E, and 22E are cross-sectional views taken along line E-E′ in FIG. 2.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

As used herein, “an element A is at a higher level than element B” or “an element A is at a lower level than element B” refers to at least one surface of element A that is not coplanar with at least one surface of element B and/or at least one surface of element A being spaced apart from a reference element by a different distance than element B and the reference element. As an example, “an element A is at a higher level than element B” refers to element A being spaced apart from a reference element by a greater distance than element B and the reference element. Components or layers described with reference to “overlap” in a particular direction may be at least partially obstructed by one another when viewed along a line extending in the particular direction or in a plane perpendicular to the particular direction.

Hereinafter, embodiments of the present disclosure will be described in detail with reference to the drawings.

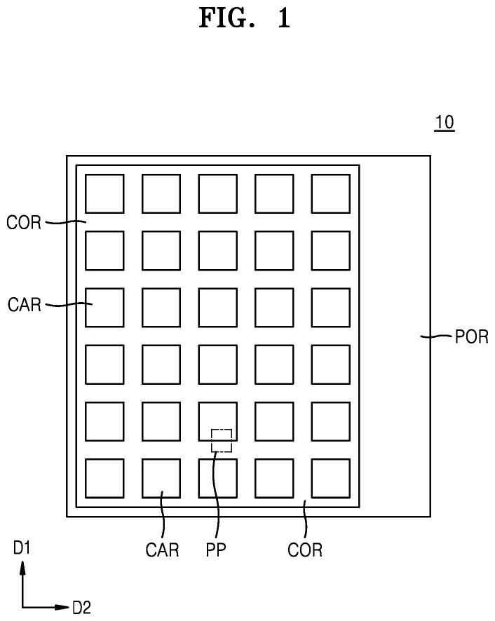

FIG. 1 is a plan view of a semiconductor device according to embodiments.

Referring to FIG. 1, a semiconductor device 10 may include cell regions CAR. Each of the cell regions CAR may include a plurality of memory cells and form a single unit cell block. The cell regions CAR may be spaced apart from each other in a first horizontal direction D1 and a second horizontal direction D2.

A core region COR may be between adjacent cell regions CAR. A sense amplifier and a write driver may be in the core region COR. A peripheral circuit region POR may be at a side of the cell regions CAR. The peripheral circuit region POR may include a row decoder and a column decoder.

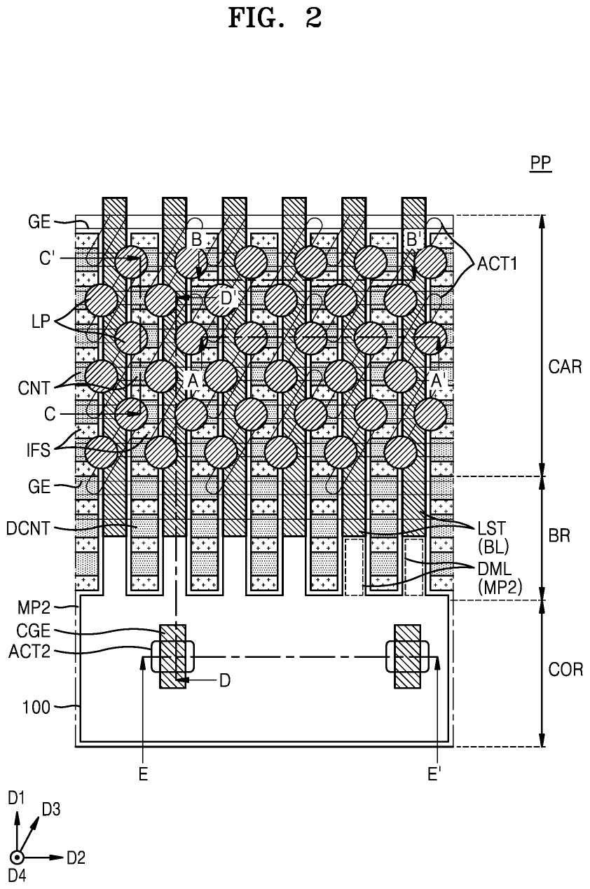

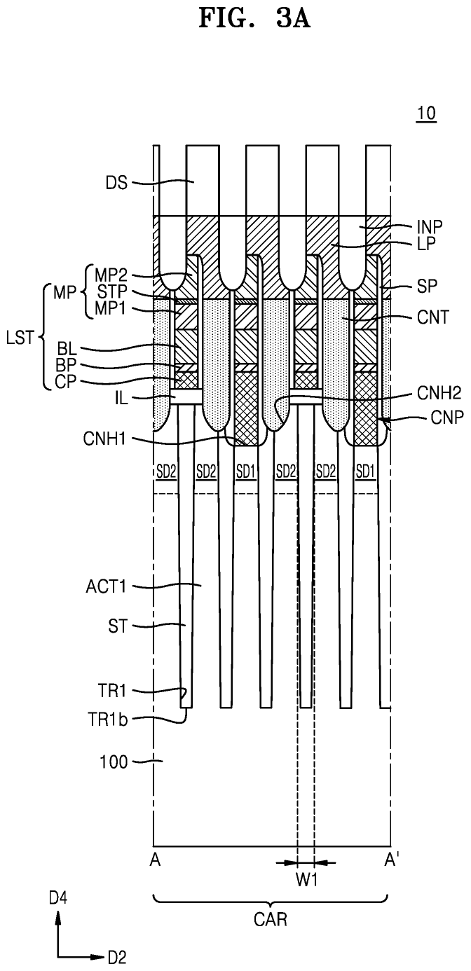

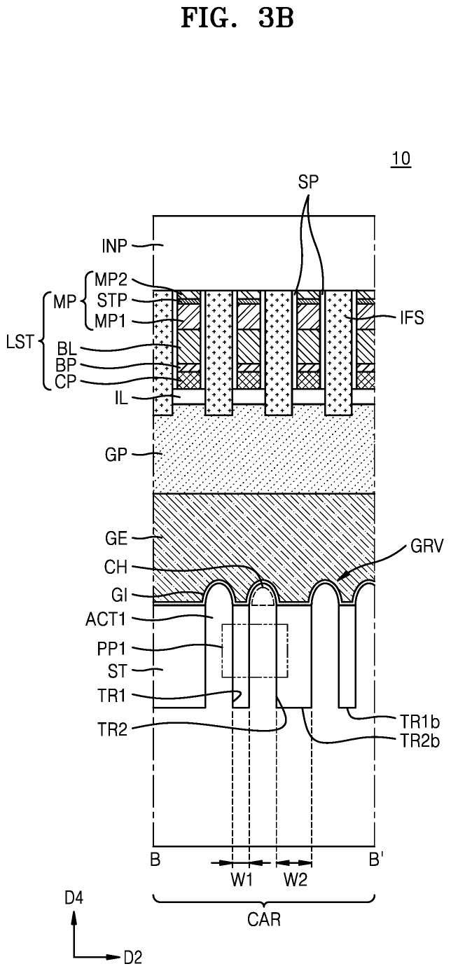

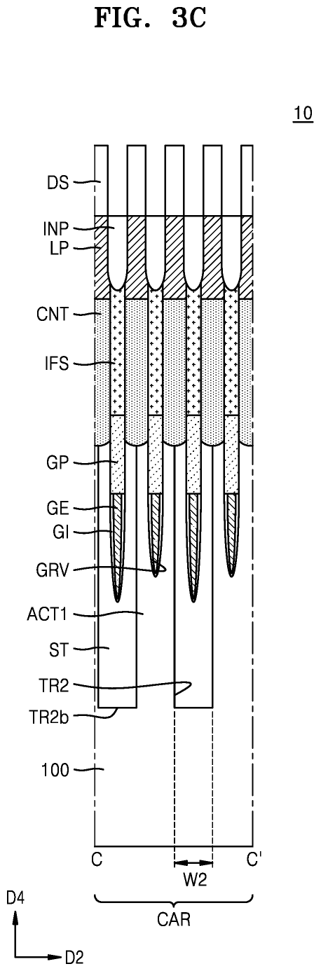

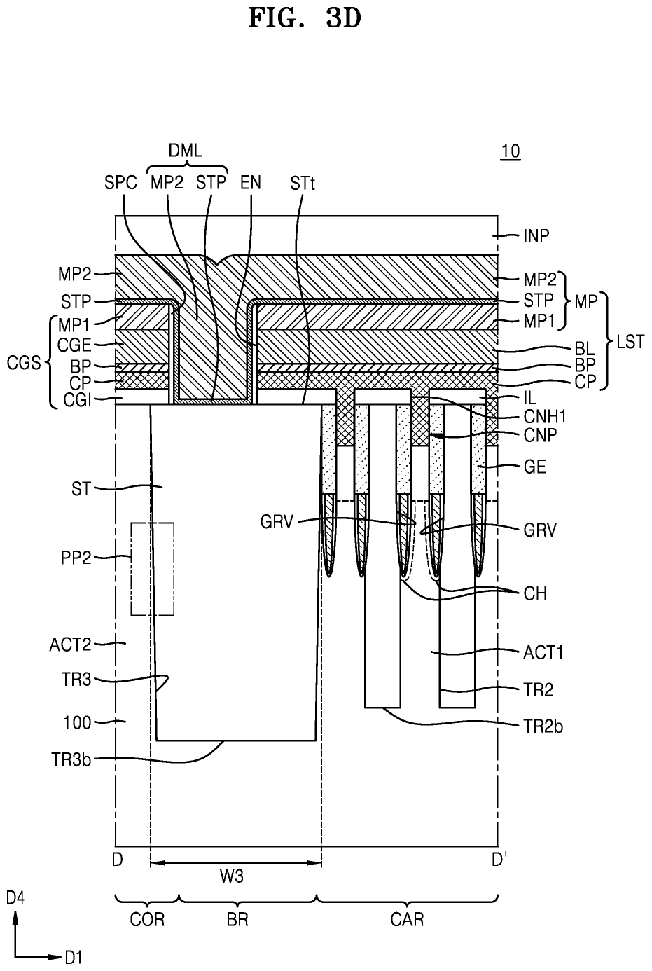

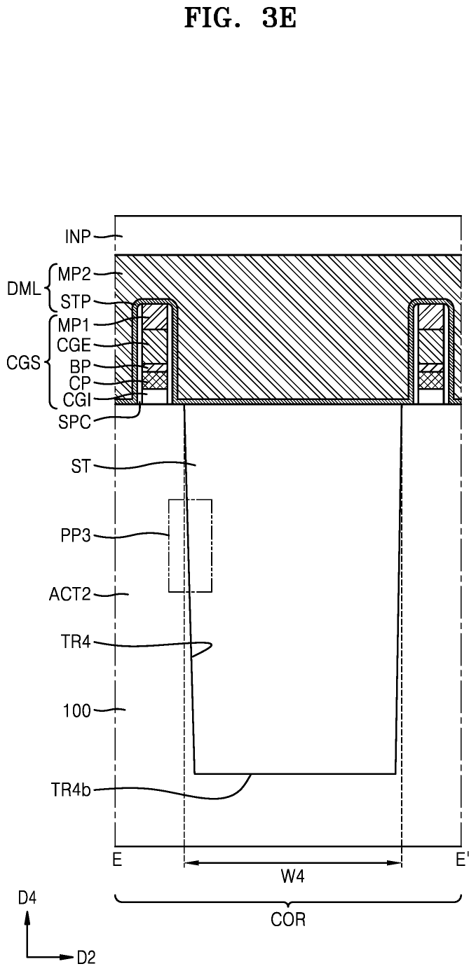

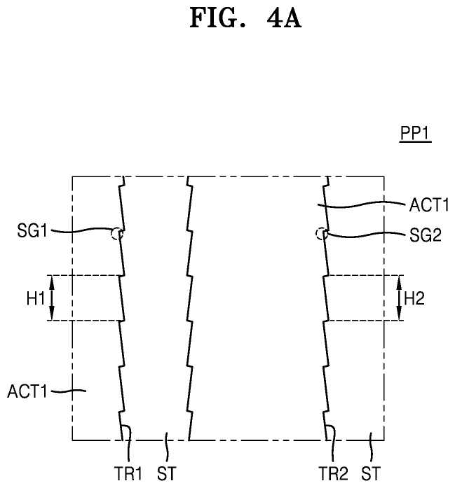

FIG. 2 is an enlarged plan view of a region PP in the boundary between one of the cell regions CAR and the core region COR in FIG. 1. FIG. 3A is a cross-sectional view taken along line A-A′ in FIG. 2, FIG. 3B is a cross-sectional view taken along line B-B′ in FIG. 2, FIG. 3C is a cross-sectional view taken along line C-C′ in FIG. 2, FIG. 3D is a cross-sectional view taken along line D-D′ in FIG. 2, and FIG. 3E is a cross-sectional view taken along line E-E′ in FIG. 2.

Referring to FIG. 2, a substrate 100 may include a cell region CAR, a boundary region BR, and the core region COR. A plurality of memory cells may be provided in the cell region CAR. The boundary region BR may be between the cell region CAR and the core region COR. The boundary region BR may neutralize process differences according to differences between a structure in the cell region CAR and a structure in the core region COR. The boundary region BR may connect the structure in the cell region CAR to the structure in the core region COR.

The substrate 100 may include a bulk silicon substrate, a silicon-on-insulator (SOI) substrate, a germanium substrate, a germanium-on-insulator (GOI) substrate, a silicon germanium substrate, or a substrate of an epitaxial thin film formed by selective epitaxial growth (SEG).

The cell region CAR is described in detail with reference to FIGS. 2 to 3D. An isolation film ST defining first active patterns ACT1 may be in the cell region CAR of the substrate 100. The first active patterns ACT1 may be formed by patterning an upper portion of the substrate 100. Each of the first active patterns ACT1 may extend in a third horizontal direction D3 that is parallel with the top surface of the substrate 100. In other words, each of the first active patterns ACT1 may have a long axis in the third horizontal direction D3. The first active patterns ACT1 may be two-dimensionally arranged in the first horizontal direction D1 and the second horizontal direction D2. The first active patterns ACT1 may be apart from each other in the third horizontal direction D3.

The width of each of the first active patterns ACT1 may decrease upward in a direction (i.e., a vertical direction D4) that is perpendicular to the top surface of the substrate 100. In other words, the width of each of the first active patterns ACT1 may decrease as the distance from the bottom surface of the substrate 100 and the first active patterns ACT1 increases.

Herein, the first horizontal direction D1 may be defined as a direction that is parallel with the top surface of the substrate 100. The second horizontal direction D2 may be defined as a direction that is perpendicular to the first horizontal direction D1 and parallel with the top surface of the substrate 100. The third horizontal direction D3 may be defined as a direction that intersects with the first horizontal direction D1 and the second horizontal direction D2 and is parallel with the top surface of the substrate 100. The vertical direction D4 may be defined as a direction that is perpendicular to the top surface of the substrate 100.

A first trench TR1 and a second trench TR2 may be defined among the first active patterns ACT1. The isolation film ST may be in the first trench TR1 and the second trench TR2 among the first active patterns ACT1. The first trench TR1 may be defined between two first active patterns ACT1 adjacent to each other in the second horizontal direction D2. The second trench TR2 may be defined between two first active patterns ACT1 adjacent to each other in the third horizontal direction D3.

The distance between two first active patterns ACT1 adjacent to each other in the second horizontal direction D2 may be less than the distance between two first active patterns ACT1 adjacent to each other in the third horizontal direction D3. The first trench TR1 may have a first width W1. The first width W1 may correspond to a width of the first trench TR1 in the second horizontal direction D2. The second trench TR2 may have a second width W2. The second width W2 may correspond to a width of the second trench TR2 in the first horizontal direction D1 or the second horizontal direction D2. The first width W1 may be less than the second width W2. In other words, the horizontal width of the first trench TR1 may be less than the horizontal width of the second trench TR2. In an embodiment, the vertical level of a bottom TR2b of the second trench TR2 may be substantially the same as the vertical level of a bottom TR1b of the first trench TR1 Herein, “being the same as” may refer to being mathematically identical and/or an acceptable error range of associated processes.

A first source/drain region SD1 and a pair of second source/drain regions SD2 may be provided in an upper portion of each of the first active patterns ACT1. The first source/drain region SD1 may be between a pair of second source/drain regions SD2. In other words, according to a plan view, a second source/drain region SD2, a first source/drain region SD1, and a second source/drain region SD2 may be sequentially arranged in the third horizontal direction D3.

A pair of grooves GRV may be in each of the first active patterns ACT1 (see FIG. 3C). Each of the grooves GRV may be between the first source/drain region SD1 and the second source/drain region SD2. A groove GRV may be in an upper portion of each of the first active patterns ACT1 and may extend from the top surface of each first active pattern ACT1 toward the bottom surface of the substrate 100. The bottom of the groove GRV may be higher than the bottom TR1b of the first trench TR1 and the bottom TR2b of the second trench TR2.

The upper portion of each of the first active patterns ACT1 may further include a pair of channel regions CH. According to a plan view, a channel region CH may be between the first source/drain region SD1 and the second source/drain region SD2. The channel region CH may be below the groove GRV (see FIG. 3D). Accordingly, the channel region CH may be lower than the first and second source/drain regions SD1 and SD2 (e.g., a distance between the channel region CH and the substrate 100 is less than a distance between the first and second source/drain regions SD1 and SD2 and the substrate 100).

Gate electrodes GE may intersect the first active patterns ACT1 and the isolation film ST. The gate electrodes GE may be respectively in grooves GRV. The gate electrodes GE may extend in the second horizontal direction D2 to be parallel with each other. A pair of gate electrodes GE may be on a pair of channel regions CH of each of the first active patterns ACT1. According to a plan view, a gate electrode GE may be between the first source/drain region SD1 and the second source/drain region SD2. The top surface of the gate electrode GE may be lower than the top surface of each first active pattern ACT1 (e.g., the top surface of the first source/drain region SD1 or the top surface of the second source/drain region SD2).

Referring to FIG. 3D, an upper portion of the gate electrode GE may be closer to the first source/drain region SD1 of the first active pattern ACT1 than a channel region CH. A lower portion of the gate electrode GE may be closer to the channel region CH than the first source/drain region SD1 of the first active pattern ACT1. The gate electrode GE may correspond to a word line of a memory cell.

Referring back to FIGS. 2 to 3D, a gate dielectric film GI may be between the gate electrode GE and the first active pattern ACT1. A gate capping film GP may be on the gate electrode GE. The gate capping film GP may cover or overlap the top surface of the gate electrode GE. The top surface of the gate capping film GP may be coplanar with the top surface of the first active pattern ACT1.

The gate electrode GE may include conductive metal nitride (e.g., titanium nitride or tantalum nitride) and/or a metal material (e.g., titanium, tantalum, tungsten, copper, or aluminum). The gate dielectric film GI may include a silicon oxide film, a silicon nitride film, a silicon oxynitride film, and/or a high-permittivity material. For example, the high-permittivity material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof. The gate capping film GP may include a silicon oxide film, a silicon nitride film, and/or a silicon oxynitride film.

A buffer film IL may be on the substrate 100. The buffer film IL may include first contact holes CNH1 respectively exposing first source/drain regions SD1 of respective first active patterns ACT1. In an embodiment, the buffer film IL may include a first insulating film and a second insulating film stacked on the first insulating film. The second insulating film may have a higher permittivity than the first insulating film. For example, the first insulating film may include a silicon oxide film and the second insulating film may include a silicon oxynitride film.

Line structures LST may be on the buffer film IL and may extend in the first horizontal direction D1 to be parallel with each other. The line structures LST may be arranged in the second horizontal direction D2. According to a plan view, the line structures LST may intersect the gate electrodes GE at right angles (see FIG. 2). Spacers SP may be respectively on opposite sidewalls of each of the line structures LST. The spacers SP may include a silicon oxide film, a silicon nitride film, and/or a silicon oxynitride film.

In an embodiment, each of the spacers SP may include a first spacer, a second spacer, and a third spacer. The first spacer may directly cover or overlap a sidewall of a line structure LST. The second spacer may be between the first spacer and the third spacer. The second spacer may include an insulating material, which has a lower permittivity than the first and third spacers. For example, each of the first and third spacers may include a silicon nitride film and the second spacer may include a silicon oxide film. As another example, the second spacer may include an air spacer.

Each of the line structures LST may include a conductive pattern CP, a barrier pattern BP, a bit line BL, and a mask pattern MP, which are sequentially stacked on each other. The conductive pattern CP may include a contact portion CNP, which at least partially or completely fills a first contact hole CNH1 and is in contact with a first source/drain region SD1. In detail, the contact portion CNP may extend toward the bottom surface of the substrate 100 through the buffer film IL. The contact portion CNP may be in direct contact with the first source/drain region SD1.

The barrier pattern BP may suppress a metal material of the bit line BL from diffusing to the conductive pattern CP. The bit line BL may be electrically connected to the first source/drain region SD1 through the barrier pattern BP and the conductive pattern CP.

The conductive pattern CP may include a doped semiconductor material (e.g., doped silicon, doped germanium, etc.). The barrier pattern BP may include conductive metal nitride (e.g., titanium nitride or tantalum nitride). The bit line BL may include a metal material (e.g., titanium, tantalum, tungsten, copper, or aluminum).

The mask pattern MP may include a first mask pattern MP1, a stopper pattern STP, and a second mask pattern MP2, which are sequentially stacked on the bit line BL. The stopper pattern STP may be between the first mask pattern MP1 and the second mask pattern MP2. Each of the first mask pattern MP1, the stopper pattern STP, and the second mask pattern MP2 may include silicon nitride or silicon oxynitride. For example, the first mask pattern MP1, the stopper pattern STP, and the second mask pattern MP2 may include the same material (e.g., silicon nitride) as one another.

Referring back to FIG. 3B, a plurality of insulating fences IFS may be on the gate capping film GP. Each of the insulating fences IFS may extend to an upper portion of the gate capping film GP through the buffer film IL.

Referring back to FIGS. 2 and 3B, the insulating fences IFS may be two-dimensionally arranged in the first horizontal direction D1 and the second horizontal direction D2. In detail, the insulating fences IFS may be arranged in the second horizontal direction D2 on the gate capping film GP, which extends in the second horizontal direction D2. The insulating fences IFS and the line structures LST may alternate with each other in the second horizontal direction D2. The insulating fences IFS arranged in the second horizontal direction D2 may vertically overlap the gate electrode GE therebelow.

Referring to FIGS. 2 to 3D, contacts CNT may extend through the buffer film IL and may be in contact with second source/drain regions SD2, respectively. Each of the contacts CNT may at least partially or completely fill a second contact hole CNH2, which is formed by partially etching an upper portion of a second source/drain region SD2. Referring back to FIG. 3A, each contact CNT may be in direct contact with the second source/drain region SD2 exposed by the second contact hole CNH2. The contact CNT may be in contact with a sidewall of a spacer SP and the top surface of the isolation film ST. The contact CNT may be separated from a line structure LST by the spacer SP. The contact CNT may include a doped semiconductor material (e.g., doped silicon, doped germanium, etc.).

Referring back to FIG. 2, the contacts CNT may be two-dimensionally arranged in the first horizontal direction D1 and the second horizontal direction D2. In detail, the contacts CNT and the line structures LST may alternate with each other in the second horizontal direction D2. The contacts CNT and the insulating fences IFS may be between two adjacent line structures LST. The contacts CNT and the insulating fences IFS between two adjacent line structures LST may alternate with each other in the first horizontal direction D1.

Referring to FIGS. 2 to 3D, landing pads LP may be respectively on the contacts CNT and be in contact with the contacts CNT, respectively. The landing pads LP may be electrically connected to the second source/drain regions SD2, respectively, through the contacts CNT. Each of the landing pads LP may be misaligned with a contact CNT connected thereto. In other words, each landing pad LP may be horizontally offset from the center of the contact CNT connected thereto (see FIGS. 2 and 3A). The landing pads LP may include a metal material (e.g., titanium, tantalum, tungsten, copper, or aluminum).

An insulating pattern INP may be on a plurality of mask patterns MP. The insulating pattern INP in the cell region CAR may define the planar shape of the landing pads LP. Adjacent landing pads LP may be separated from each other by the insulating pattern INP.

Data storage elements DS may be respectively on the landing pads LP. In detail, each of the data storage elements DS may be electrically connected to a second source/drain region SD2 through a landing pad LP and a contact CNT. According to an embodiment, each of the data storage elements DS may correspond to a capacitor that stores data. For example, the data storage elements DS may include lower electrodes respectively connected to the landing pads LP, an upper electrode covering or overlapping the lower electrodes, and a dielectric film between the lower electrodes and the upper electrode. The upper electrode may correspond to a common electrode which covers or overlaps the lower electrodes in common.

Each of the lower electrodes may have a hollow cylinder shape. Each of the lower electrodes may include impurity-doped silicon, metal such as tungsten, or a conductive metal compound such as titanium nitride. The dielectric film may include a high-permittivity material, such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof. The upper electrode may include doped silicon, Ru, RuO, Pt, PtO, Ir, IrO, SRO(SrRuO), BSRO((Ba, Sr)RuO), CRO(CaRuO), BaRuO, La(Sr, Co)O, Ti, TiN, W, WN, Ta, TaN, TiAlN, TiSiN, TaAlN, TaSiN, or a combination thereof.

The boundary region BR and the core region COR are described in detail with reference to FIGS. 2, 3D, and 3E below. A third trench TR3 may be defined between the cell region CAR and the core region COR of the substrate 100. In other words, the third trench TR3 may be defined on the boundary region BR of the substrate 100. The isolation film ST may be in the third trench TR3.

At least one second active pattern ACT2 may be in the core region COR. For example, the third trench TR3 may be defined between a first active pattern ACT1 of the cell region CAR and the second active pattern ACT2 of the core region COR. Although it is illustrated in FIG. 2 that the second active pattern ACT2 has a quadrangular shape, embodiments are not limited thereto. The second active pattern ACT2 may have any shape.

The third trench TR3 may have a third width W3. The third width W3 may correspond to a width of the third trench TR3 in the first horizontal direction D1. The third width may be greater than any one of the first width W1 and the second width W2. In other words, the horizontal width of the third trench TR3 may be greater than the horizontal width of each of the first trench TR1 and the second trench TR2. In an embodiment, the vertical level of a bottom TR3b of the third trench TR3 may be lower than any one of the vertical level of the bottom TR1b of the first trench TR1 and the vertical level of the bottom TR2b of the second trench TR2.

A core gate structure CGS may be in the core region COR. The core gate structure CGS may include a core gate insulating film CGI, a conductive pattern CP, a barrier pattern BP, a core gate electrode CGE, and a first mask pattern MP1, which are sequentially stacked on the second active pattern ACT2. For example, the core gate structure CGS and the second active pattern ACT2 may form a transistor of a sense amplifier of the core region COR.

Elements of the core gate structure CGS may be formed by substantially the same processes as elements of a line structure LST of the cell region CAR. Each of the elements of the core gate structure CGS may be at substantially the same level as a corresponding element among the elements of the line structure LST. In other words, the core gate insulating film CGI may correspond to the buffer film IL and the core gate electrode CGE may correspond to the bit line BL.

In an embodiment, an end of the core gate structure CGS may extend to be on the isolation film ST of the boundary region BR. In other words, at least a portion of the core gate structure CGS may vertically overlap the isolation film ST, which fills the third trench TR3 of the boundary region BR.

A sidewall spacer SPC may be on a sidewall of the core gate structure CGS. As shown in FIG. 3D, the sidewall spacer SPC may be on the isolation film ST of the boundary region BR. As shown in FIG. 3E, the sidewall spacer SPC may be on each of opposite sidewalls of the core gate structure CGS of the core region COR. The sidewall spacer SPC may include at least one selected from the group consisting of a silicon oxide film, a silicon nitride film, and a silicon oxynitride film.

Referring to FIG. 3D, an end EN of the line structure LST may extend to be on the isolation film ST of the boundary region BR. A capping pattern DML may be connected to the end EN of the line structure LST. The capping pattern DML may be on the isolation film ST of the boundary region BR. The capping pattern DML may extend in the opposite direction to the first horizontal direction D1 from the end EN of the line structure LST toward the core region COR. The capping pattern DML and the line structure LST connected to the capping pattern DML may be aligned with each other in the first horizontal direction D1. The dimension of the capping pattern DML may be substantially the same as that of the line structure LST connected to the capping pattern DML.

Referring back to FIGS. 2, 3D, and 3E, the capping pattern DML may include a stopper pattern STP and a second mask pattern MP2. The conductive pattern CP, the barrier pattern BP, and the bit line BL may be omitted from the capping pattern DML.

The stopper pattern STP may cover or overlap the end EN of the line structure LST in the boundary region BR. The stopper pattern STP may extend from the line structure LST to the top surface of the core gate structure CGS to cover or overlap the top surface of the isolation film ST of the boundary region BR. The stopper pattern STP may cover or overlap the sidewall spacer SPC.

The second mask pattern MP2 may be on the stopper pattern STP. The second mask pattern MP2 may extend from the line structure LST to the top surface of the core gate structure CGS via the capping pattern DML. The second mask pattern MP2 of the core region COR may have a plate shape which overlaps the substrate 100 of the core region COR.

There may be a plurality of core gate structures CGS. For example, a fourth trench TR4 may be defined in the substrate 100 between two core gate structures CGS in the core region COR. The fourth trench TR4 may be between second active patterns ACT2. The isolation film ST may fill the fourth trench TR4.

The fourth trench TR4 may have a fourth width W4. The fourth width W4 may correspond to a width of the fourth trench TR4 in the first horizontal direction D1 or the second horizontal direction D2. The fourth width W4 may be greater than any one of the first width W1, the second width W2, and the third width W3. In other words, the horizontal width of the fourth trench TR4 may be greater than the horizontal width of each of the first to third trenches TR1, TR2, and TR3. In an embodiment, the fourth width W4 of the fourth trench TR4 may be less than or equal to the third width W3 of the third trench TR3. This may vary with the design of a semiconductor device. In an embodiment, the vertical level of a bottom TR4b of the fourth trench TR4 may be lower than any one of the vertical level of the bottom TR1b of the first trench TR1, the vertical level of the bottom TR2b of the second trench TR2, and the vertical level of the bottom TR3b of the third trench TR3. In an embodiment, the vertical level of a bottom TR4b of the fourth trench TR4 may be substantially the same as the vertical level of the bottom TR3b of the third trench TR3.

The insulating pattern INP may be on the second mask pattern MP2. Although not shown, at least one metal wiring line may be in the insulating pattern INP. The metal wiring line may electrically connect the bit line BL of the line structure LST to the core gate electrode CGE of the core gate structure CGS.

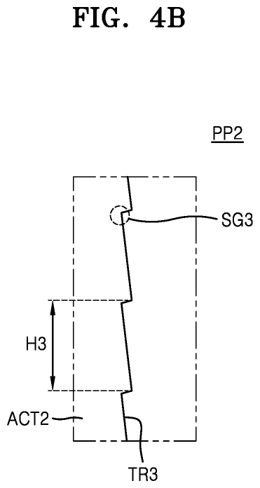

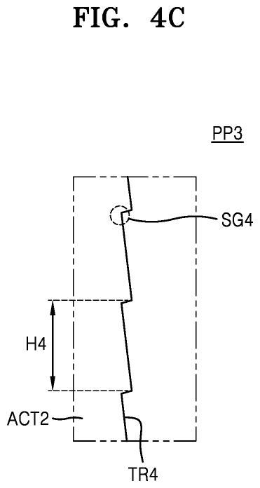

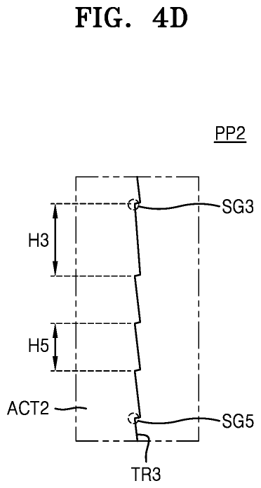

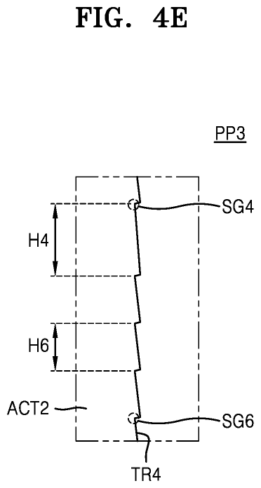

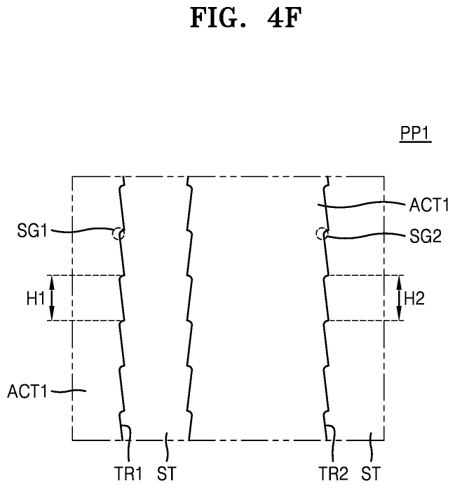

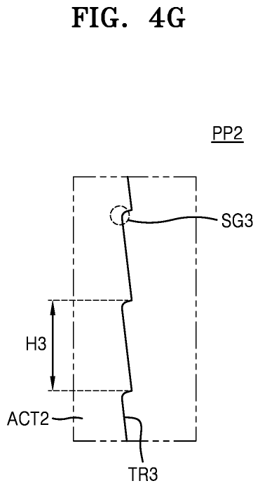

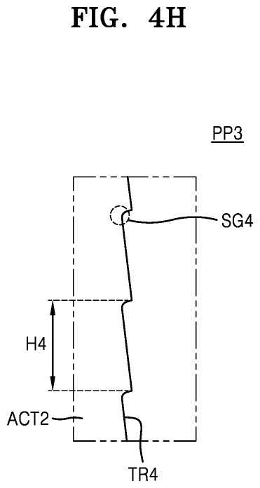

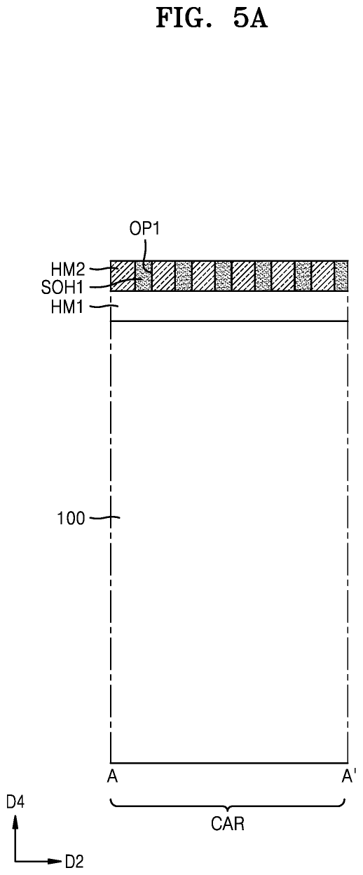

FIG. 4A is an enlarged view of a region PP1 in FIG. 3B, FIG. 4B is an enlarged view of a region PP2 in FIG. 3D, and FIG. 4C is an enlarged view of a region PP3 in FIG. 3E.

According to an embodiment, the first trench TR1, the second trench TR2, the third trench TR3, and the fourth trench TR4 are described in detail with reference to FIGS. 4A to 4C below.

FIG. 4A is an enlarged view of the region PP1 in FIG. 3B. In detail, FIG. 4A is an enlarged view of the sidewalls of the first trench TR1 and a sidewall of the second trench TR2. Referring to FIG. 4A, an inner sidewall of the first trench TR1 may include a first recess SG1 that extends into a first active pattern ACT1. Here, the first recess SG1 may refer to a portion of the first trench TR1, in which the slope of the inner sidewall of the first trench TR1 changes rapidly. For example, a boundary portion between a first portion of the inner sidewall of the first trench TR1, which has a first tilt angle, and a second portion of the inner sidewall of the first trench TR1, which has a second tilt angle that is different from the first tilt angle, may be referred to as the first recess SG1. There may be a plurality of first recesses SG1. The plurality of first recesses SG1 may be formed because the first trench TR1 is formed by a plurality of etch cycles rather than by a single etching process. During a process of forming the first trench TR1, one first recess SG1 may be formed in each etch cycle. This may be because of the characteristics of an etch cycle. The etch cycle may include a break-through (BT) step, a passivation step, and a main etch (ME) step, which are sequentially performed. The BT step may remove a natural oxide film from the surface of an etch target. The passivation step may increase an etch selectivity of the etch target with respect to other materials and protect the sidewall of the etch target. The ME step may etch the etch target. In the case of an ideal process, a passivation layer (e.g., an oxide film) formed in the passivation step may be completely removed after a single etch cycle. However, due to a limit in the process, the passivation layer (e.g., an oxide film) formed in the passivation step may not be completely removed from the sidewall of the etch target after a single etch cycle. In this case, the thickness of the passivation layer on an upper portion of the sidewall of the etch target may become greater than a target thickness in the passivation step of a subsequent etch cycle and the passivation layer on a lower portion of the sidewall of the etch target may be relatively thin. Accordingly, the relatively thin passivation layer on the lower portion of the sidewall of the etch target may be easily removed in the ME step so that the first recess SG1 may be formed.

The first recess SG1 and a linear portion (e.g., a straight line), which extends from the first recess SG1, may repeatedly appear in the inner sidewall of the first trench TR1. This may be because of the characteristics of the etch cycle described above. A first height H1 may correspond to the distance between two vertically adjacent first recesses SG1. The first height H1 may indicate an etching depth of a single etch cycle.

An inner sidewall of the second trench TR2 may include a second recess SG2 that extends into a first active pattern ACT1. There may be a plurality of second recesses SG2. The plurality of second recesses SG2 may be formed because the second trench TR2 is formed by a plurality of etch cycles rather than by a single etching process. During a process of forming the second trench TR2, one second recess SG2 may be formed in each etch cycle. This may be because of the characteristics of the etch cycle described above.

The second recess SG2 and a linear portion (e.g., a straight line), which extends from the second recess SG2, may repeatedly appear in the inner sidewall of the second trench TR2. This may be because of the characteristics of the etch cycle described above. A second height H2 may correspond to the distance between two vertically adjacent second recesses SG2. The second height H2 may indicate an etching depth of a single etch cycle. The second height H2 may be substantially the same as the first height H1. This may be because the first trench TR1 and the second trench TR2 are simultaneously formed.

FIG. 4B is an enlarged view of the region PP2 in FIG. 3D. In detail, FIG. 4B is an enlarged view of a sidewall of the third trench TR3. Referring to FIG. 4B, an inner sidewall of the third trench TR3 may include a third recess SG3 extending into a first active pattern ACT1 or a second active pattern ACT2. There may be a plurality of third recesses SG3. The plurality of third recesses SG3 may be formed because the third trench TR3 is formed by a plurality of etch cycles rather than by a single etching process. During a process of forming the third trench TR3, one third recess SG3 may be formed in each etch cycle. This may be because of the characteristics of an etch cycle.

The third recess SG3 and a linear portion (e.g., a straight line), which extends from the third recess SG3, may repeatedly appear in the inner sidewall of the third trench TR3. This may be because of the characteristics of the etch cycle described above. A third height H3 may correspond to the distance between two vertically adjacent third recesses SG3. The third height H3 may indicate an etching depth of a single etch cycle. The third height H3 may be greater than any one of the first height H1 and the second height H2. This may be because the third trench TR3 is formed separately from the first trench TR1 and the second trench TR2. The etching depth of an etch cycle may vary with process variables, such as a gas flow rate, injection time, and temperature. In other words, the third height H3 may be greater than any one of the first height H1 and the second height H2 because the process variables of an etch cycle for the third trench TR3 are different from those of an etch cycle for each of the first trench TR1 and the second trench TR2.

FIG. 4C is an enlarged view of the region PP3 in FIG. 3E. In detail, FIG. 4C is an enlarged view of a sidewall of the fourth trench TR4. Referring to FIG. 4C, an inner sidewall of the fourth trench TR4 may include a fourth recess SG4 extending into a second active pattern ACT2. There may be a plurality of fourth recesses SG4. The plurality of fourth recesses SG4 may be formed because the fourth trench TR4 is formed by a plurality of etch cycles rather than by a single etching process. During a process of forming the fourth trench TR4, one fourth recess SG4 may be formed in each etch cycle. This may be because of the characteristics of an etch cycle.

The fourth recess SG4 and a linear portion (e.g., a straight line), which extends from the fourth recess SG4, may repeatedly appear in the inner sidewall of the fourth trench TR4. This may be because of the characteristics of the etch cycle described above. A fourth height H4 may correspond to the distance between two vertically adjacent fourth recesses SG4. The fourth height H4 may indicate an etching depth of a single etch cycle. The fourth height H4 may be greater than any one of the first height H1 and the second height H2. This may be because the fourth trench TR4 is formed separately from the first trench TR1 and the second trench TR2. As described above, this may be because the process variables of an etch cycle for the fourth trench TR4 are different from those of an etch cycle for each of the first trench TR1 and the second trench TR2.

The fourth height H4 may be substantially the same as the third height H3. This may be because the fourth trench TR4 and the third trench TR3 are simultaneously formed. In an embodiment, the fourth height H4 may be greater than the third height H3. This may be because the fourth width W4 of the fourth trench TR4 is greater than the third width W3 of the third trench TR3, as described above with reference to FIGS. 3D and 3E. Although the fourth trench TR4 and the third trench TR3 are simultaneously formed, the etching depth of the fourth trench TR4 may be different from that of the third trench TR3 because of the difference between the fourth width W4 of the fourth trench TR4 and the third width W3 of the third trench TR3.

FIG. 4D is an enlarged view of the region PP1 in FIGS. 3B and 4E is an enlarged view of the region PP3 in FIG. 3E according to some embodiments. Detailed descriptions of technical features overlapping with those described above with reference to FIGS. 4A to 4C are omitted, and differences from FIGS. 4A to 4C are described in detail.

FIG. 4D is an enlarged view of the region PP2 in FIG. 3D. In detail, FIG. 4D is an enlarged view of a sidewall of the third trench TR3. Referring to FIG. 4D, the inner sidewall of the third trench TR3 may include the third recess SG3 and a fifth recess SG5, which extend into the second active pattern ACT2. There may be a plurality of third recesses SG3 and a plurality of fifth recesses SG5. The third recesses SG3 may be above the fifth recesses SG5 in the third trench TR3. In other words, a fifth recess SG5 furthest from the bottom (TR3b in FIG. 3D) of the third trench TR3 among the fifth recesses SG5 may be below a third recess SG3 closest to the bottom (TR3b in FIG. 3D) of the third trench TR3 among the third recesses SG3.

Like the third recesses SG3 described above, the plurality of fifth recesses SG5 may be formed because the third trench TR3 is formed by a plurality of etch cycles rather than by a single etching process. During a process of forming the third trench TR3, one fifth recess SG5 may be formed in each etch cycle. This may be because of the characteristics of an etch cycle.

The fifth recess SG5 and a linear portion (e.g., a straight line), which extends from the fifth recess SG5, may repeatedly appear in the inner sidewall of the third trench TR3. This may be because of the characteristics of the etch cycle described above. The third height H3 may correspond to the distance between two vertically adjacent third recesses SG3. A fifth height H5 may correspond to the distance between two vertically adjacent fifth recesses SG5. Each of the third height H3 and the fifth height H5 may indicate an etching depth of a single etch cycle. The fifth height H5 may be less than the third height H3. This may be because the process variables of an etch cycle, in which the fifth recesses SG5 are formed, are different from those of an etch cycle, in which the third recesses SG3 are formed. The fifth height H5 may be substantially the same as each of the first height H1 and the second height H2 in FIG. 4A. This may be because the process variables of an etch cycle, in which the fifth recesses SG5 are formed, are the same as those of an etch cycle, in which the first recesses SG1 and the second recesses SG2 are formed. In other words, the fifth height H5 may be substantially the same as each of the first height H1 and the second height H2 because the fifth recesses SG5 are simultaneously formed with the first recesses SG1 and the second recesses SG2.

FIG. 4E is an enlarged view of the region PP3 in FIG. 3E. In detail, FIG. 4E is an enlarged view of the sidewall of the fourth trench TR4. Referring to FIG. 4E, the sidewall of the fourth trench TR4 may include a fourth recess SG4 and a sixth recess SG6, which extend into the second active pattern ACT2. There may be a plurality of fourth recesses SG4 and a plurality of sixth recesses SG6. The fourth recesses SG4 may be above the sixth recesses SG6 in the fourth trench TR4. In other words, a sixth recess SG6 furthest from the bottom (TR4b in FIG. 3E) of the fourth trench TR4 among the sixth recesses SG6 may be below a fourth recess SG4 closest to the bottom (TR4b in FIG. 3E) of the fourth trench TR4 among the fourth recesses SG4.

Like the fourth recesses SG4 described above, the plurality of sixth recesses SG6 may be formed because the fourth trench TR4 is formed by a plurality of etch cycles rather than by a single etching process. During a process of forming the fourth trench TR4, one sixth recess SG6 may be formed in each etch cycle. This may be because of the characteristics of an etch cycle.

The sixth recess SG6 and a linear portion (e.g., a straight line), which extends from the sixth recess SG6, may repeatedly appear in the inner sidewall of the fourth trench TR4. This may be because of the characteristics of the etch cycle described above. The fourth height H4 may correspond to the distance between two vertically adjacent fourth recesses SG4. A sixth height H6 may correspond to the distance between two vertically adjacent sixth recesses SG6. Each of the fourth height H4 and the sixth height H6 may indicate an etching depth of a single etch cycle. The sixth height H6 may be less than the fourth height H4. This may be because the process variables of an etch cycle, in which the sixth recesses SG6 are formed, are different from those of an etch cycle, in which the fourth recesses SG4 are formed. The sixth height H6 may be substantially the same as each of the first height H1 and the second height H2 in FIG. 4A. This may be because the process variables of an etch cycle, in which the sixth recesses SG6 are formed, are the same as those of an etch cycle, in which the first recesses SG1 and the second recesses SG2 are formed. In other words, the sixth height H6 may be substantially the same as each of the first height H1 and the second height H2 because the sixth recesses SG6 are simultaneously formed with the first recesses SG1 and the second recesses SG2.

FIG. 4F is an enlarged view of the region PP1 in FIG. 3B, FIG. 4G is an enlarged plan view of the region PP2 in FIGS. 3D, and 4H is an enlarged view of the region PP3 in FIG. 3E, according to some embodiments. Detailed descriptions of technical features overlapping with those described above with reference to FIGS. 4A to 4C are omitted, and differences from FIGS. 4A to 4C are described in detail.

Referring to FIGS. 4F to 4H, each of a first recess SG1, a second recess SG2, a third recess SG3, and a fourth recess SG1 may have a nonlinear shape (e.g., a smooth, curved shape). The inner sidewall of each of the first to fourth trenches TR1 to TR4 may have a nonlinear shape (e.g., a wavy profile). The first recess SG1 and a linear portion or a curve, which extends from the first recess SG1, may repeatedly appear in the inner sidewall of the first trench TR1. The second recess SG2 and a linear portion or a curve, which extends from the second recess SG2, may repeatedly appear in the inner sidewall of the second trench TR2. The third recess SG3 and a linear portion or a curve, which extends from the third recess SG3, may repeatedly appear in the inner sidewall of the third trench TR3. The fourth recess SG4 and a linear portion or a curve, which extends from the fourth recess SG4, may repeatedly appear in the inner sidewall of the fourth trench TR4.

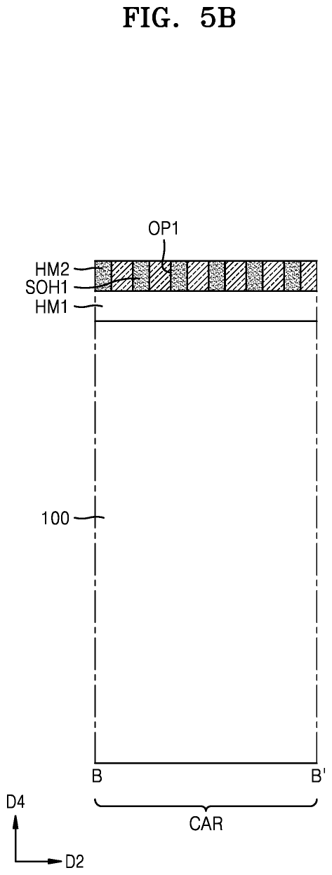

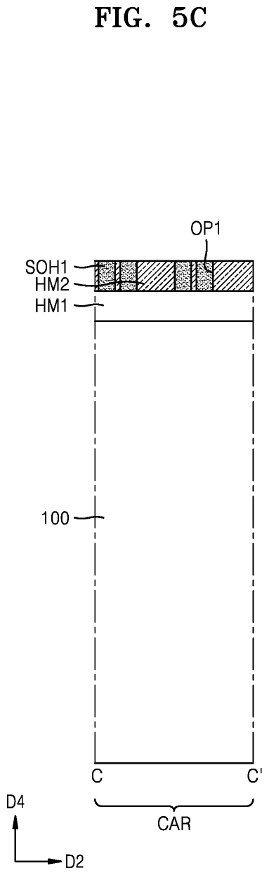

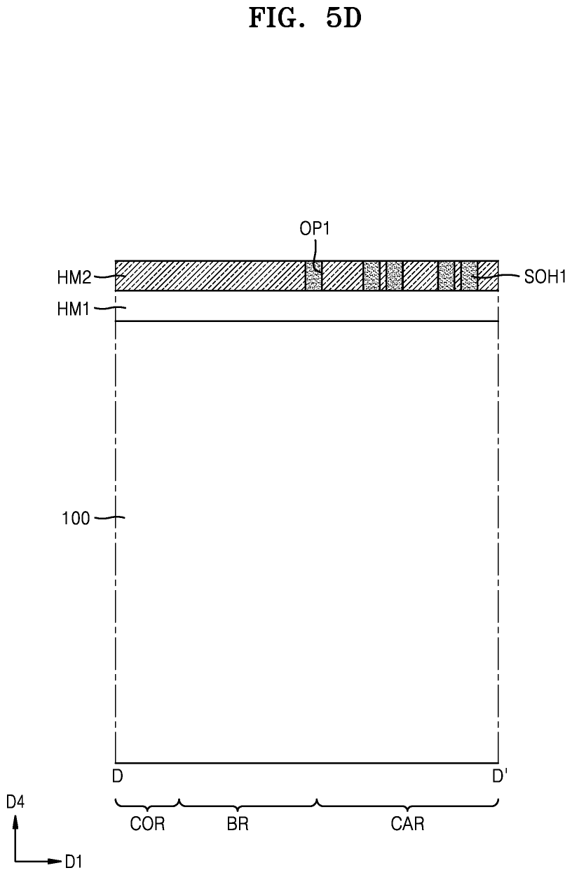

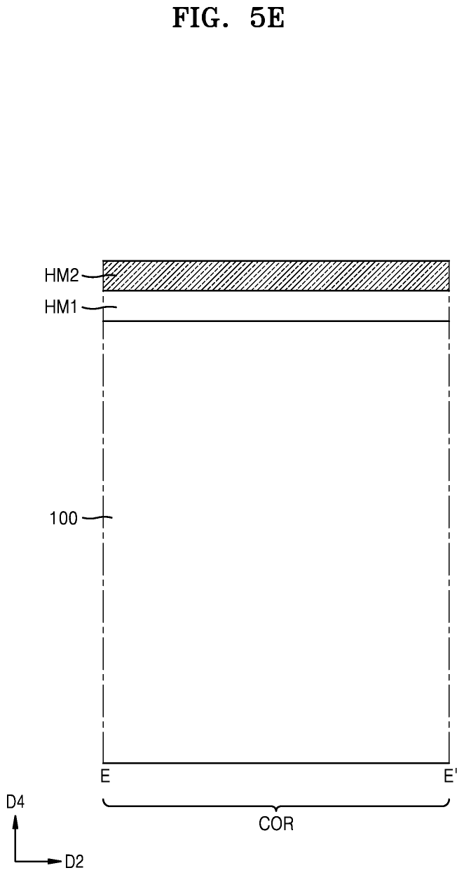

FIGS. 5A to 19C are diagrams illustrating a method of manufacturing a semiconductor device according to embodiments. In detail, FIGS. 5A, 6A, 7A, 8A, 9A, 10A, 11A, 12A, 13A, 14A, 15A, 16A, 17A, 18A, and 19A are cross-sectional views taken along line A-A′ in FIG. 2. FIGS. 5B, 6B, 7B, 8B, 9B, 10B, 11B, 12B, 13B, 14B, 15B, 16B, 17B, 18B, and 19B are cross-sectional views taken along line B-B′ in FIG. 2. FIGS. 5C, 6C, 7C, 8C, 9C, 10C., 11C, 12C, 13C, 14C, 15C, 16C, 17C, 18C, and 19C are cross-sectional views taken along line C-C′ in FIG. 2. FIGS. 5D, 6D, 7D, 8D, 9D, 10D, 11D, 12D, 13D, 14D, 15D, 16D, 17D, and 18D are cross-sectional views taken along line D-D′ in FIG. 2. FIGS. 5E, 6E, 7E, 8E, 9E, 10E, 11E, 12E, 13E, 14E, 15E, 16E, 17E, and 18E are cross-sectional views taken along line E-E′ in FIG. 2.

Referring to FIGS. 5A to 5E, the substrate 100 including a cell region CAR, a boundary region BR, and a core region COR may be provided. A first hardmask HM1 and a second hardmask HM2 may be sequentially formed on the substrate 100. First openings OP1 may be formed by patterning the second hardmask HM2. A first auxiliary mask SOH1 may be formed in the first openings OP1. A region of the first openings OP1 may vertically overlap a portion, in which first trenches TR1 and second trenches TR2 are to be formed in the cell region CAR and the boundary region BR. Accordingly, the first openings OP1 may not be formed in the core region COR.

The forming of the first auxiliary mask SOH1 may include coating the top surface of the second hardmask HM2 with a first auxiliary mask film (not shown) in the first openings OP1 and performing an etch back process on the first auxiliary mask film. Due to the etch back process, the vertical level of the top surface of the second hardmask HM2 may be substantially the same as the vertical level of the top surface of the first auxiliary mask SOH1. The first hardmask HM1 may include an insulating material such as silicon oxide. The second hardmask HM2 may include polysilicon. The first auxiliary mask SOH1 may include a spin-on hardmask (SOH) material.

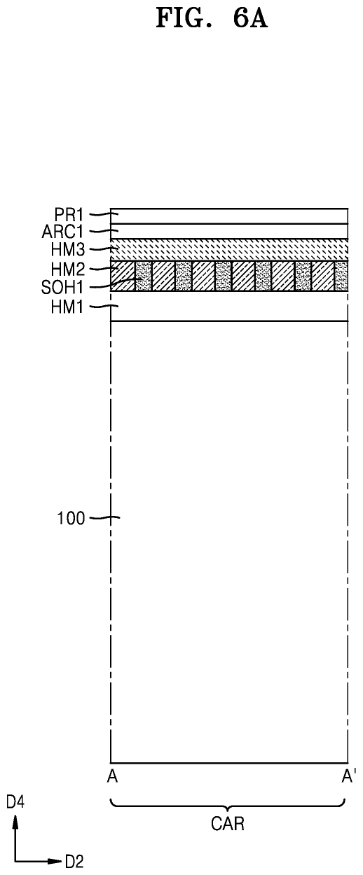

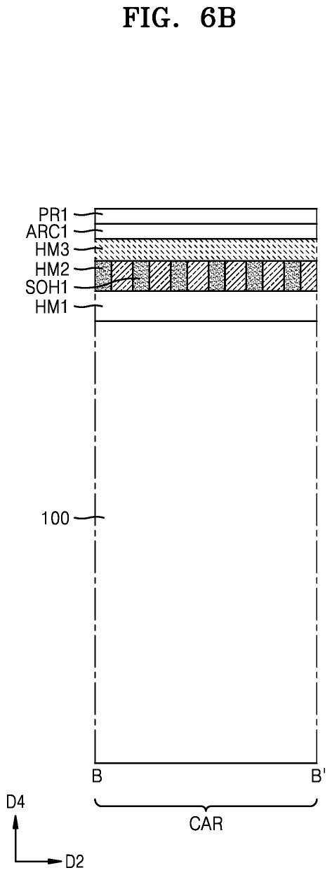

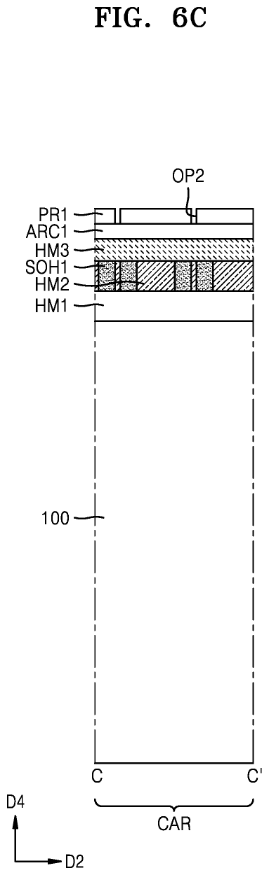

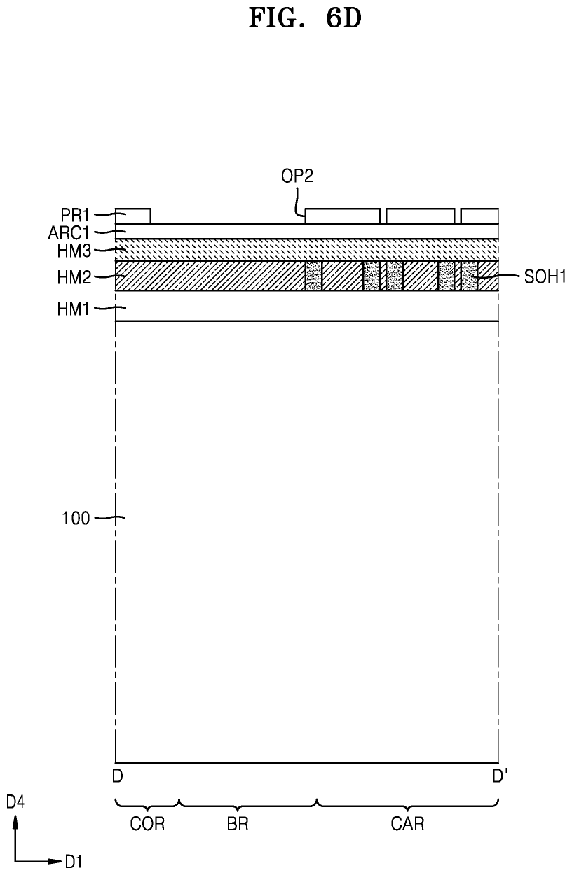

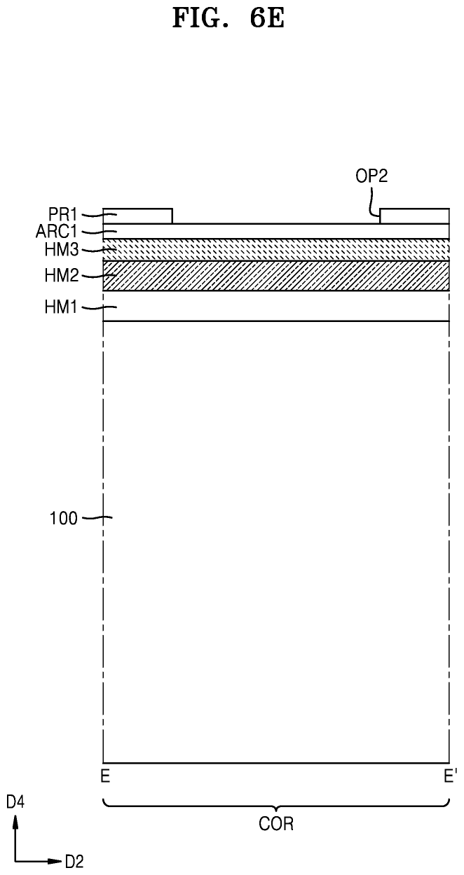

Referring to FIGS. 6A to 6E, a third hardmask HM3 may be formed on the second hardmask HM2 and the first auxiliary mask SOH1. The third hardmask HM3 may be formed throughout the cell region CAR, the boundary region BR, and the core region COR. A first anti-reflective film ARC1 may be formed on the third hardmask HM3. A first photoresist PR1 may be formed on the first anti-reflective film ARC1. The first photoresist PR1 may include second openings OP2. The top surface of the first anti-reflective film ARC1 may be partially exposed by the second openings OP2. The third hardmask HM3 may include an amorphous carbon layer (ACL). The first anti-reflective film ARC1 may include silicon oxynitride. The first photoresist PR1 may include a photoresist material.

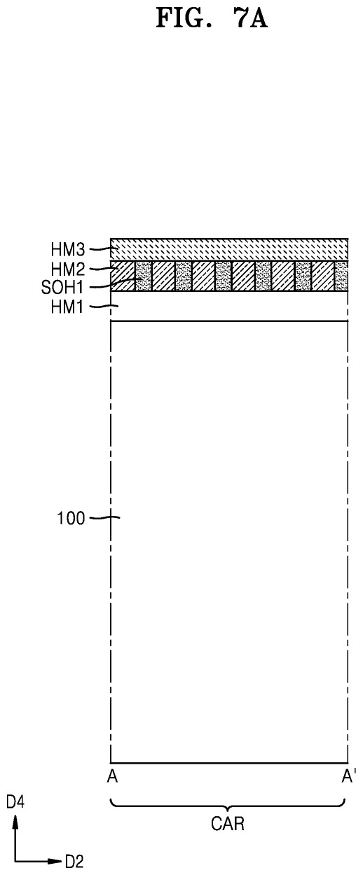

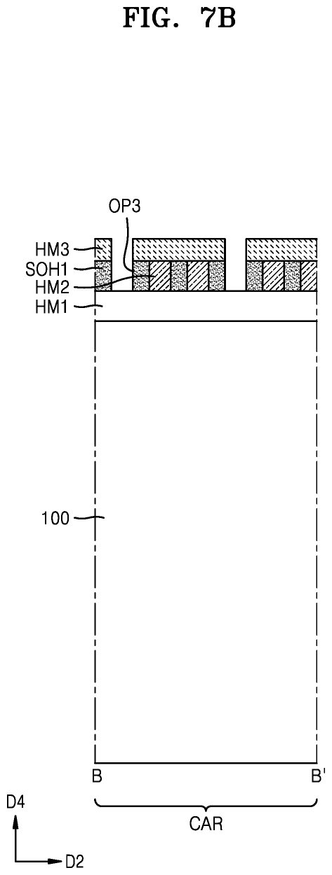

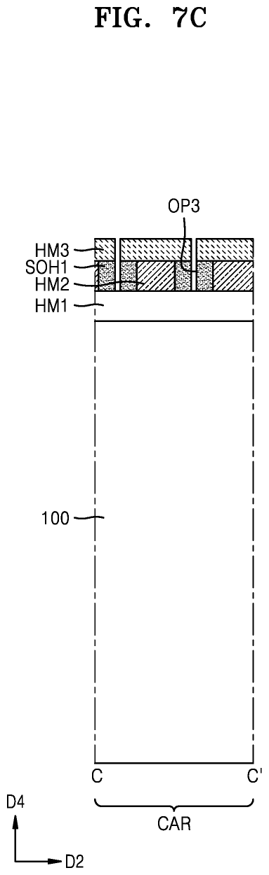

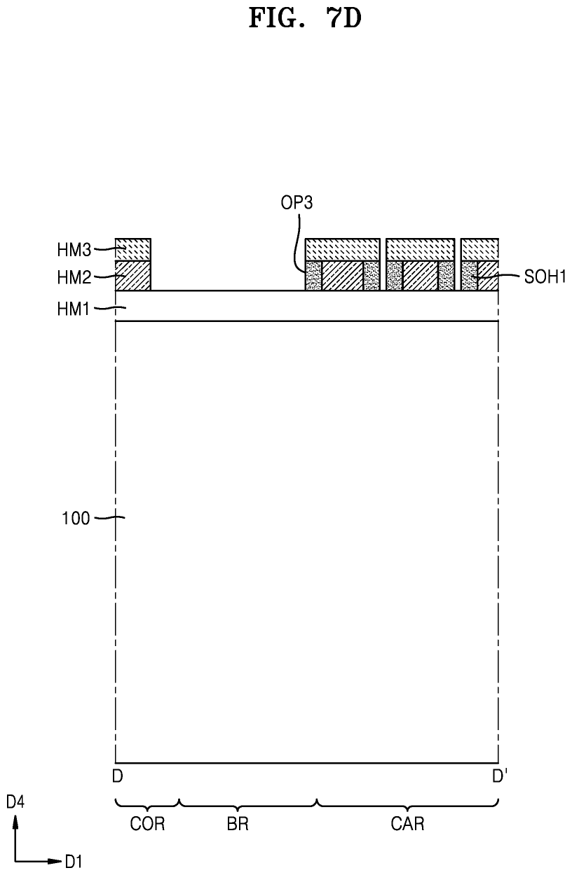

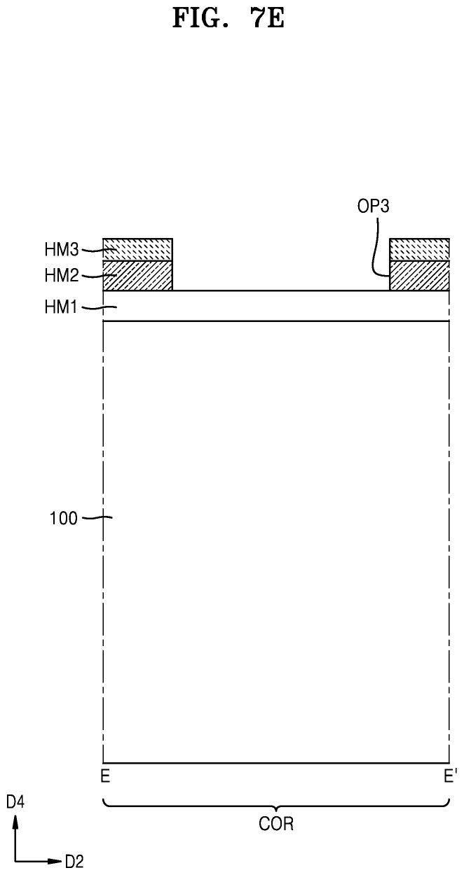

Referring to FIGS. 7A to 7E, an etching process may be performed on the third hardmask HM3 and the second hardmask HM2 through the second openings OP2. Due to the etching process, third openings OP3 may be formed through the third hardmask HM3 and the second hardmask HM2. The top surface of the first hardmask HM1 may be partially exposed by the third openings OP3. The first auxiliary mask SOH1 may also be partially exposed by the third openings OP3. During the etching process, the first anti-reflective film ARC1 may be removed. After the etching process, an ashing process may be performed to remove the first photoresist PR1.

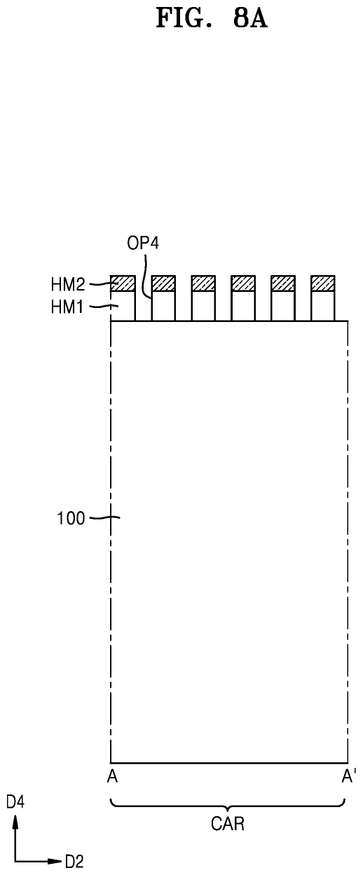

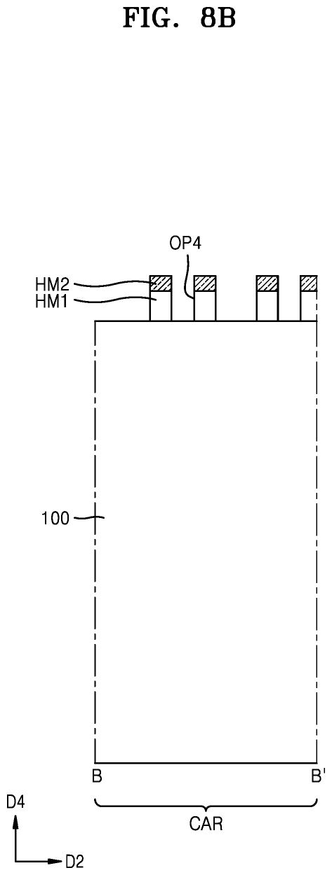

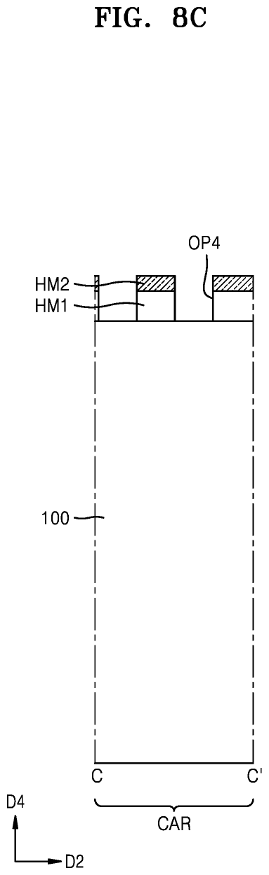

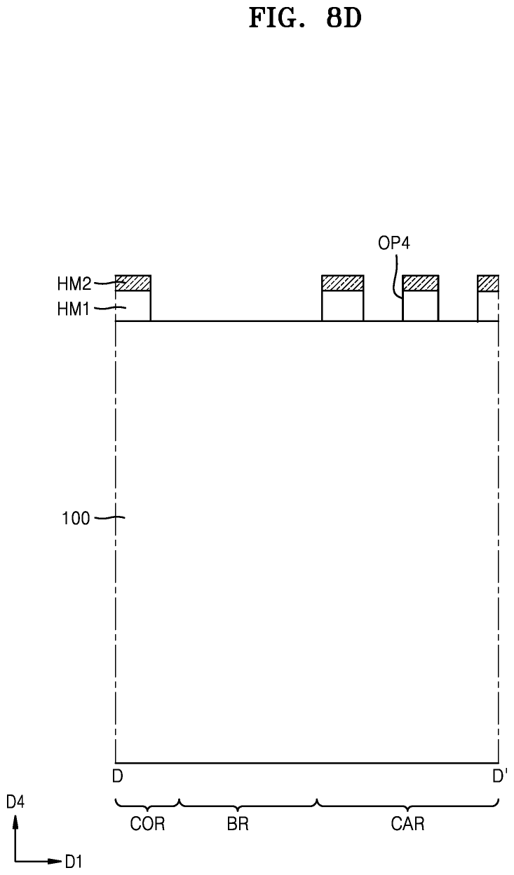

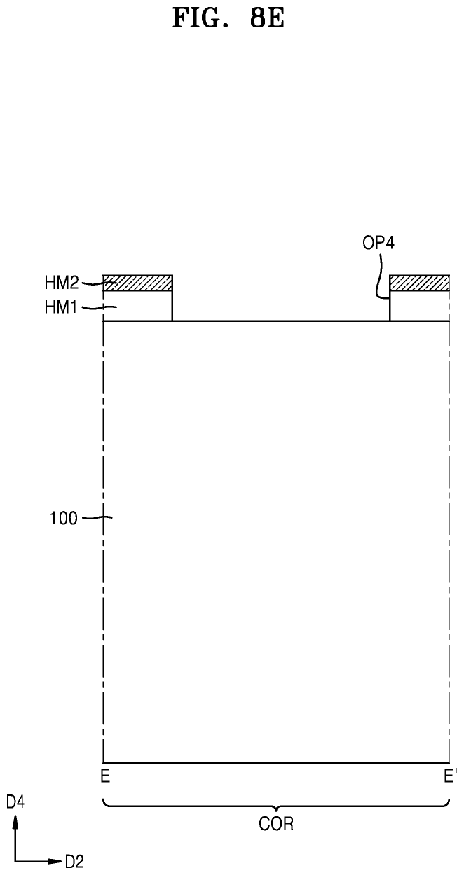

Referring to FIGS. 8A to 8E, an etching process may be performed on the first hardmask HM1 through the third openings OP3. Due to the etching process, only a portion of the first hardmask HM1, which overlaps the second hardmask HM2, may remain. Subsequently, the third hardmask HM3 and the first auxiliary mask SOH1 may be removed.

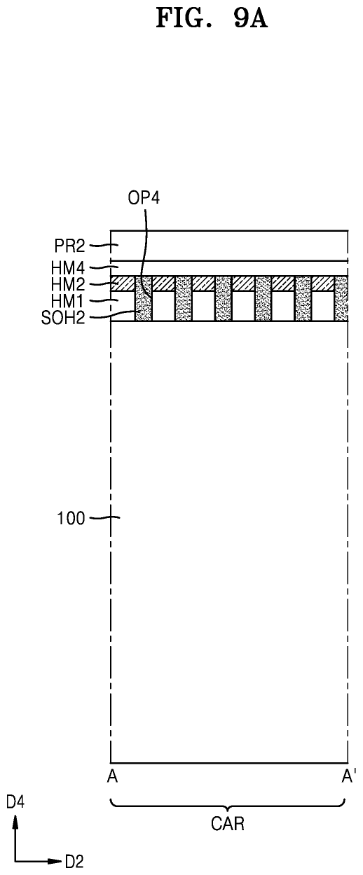

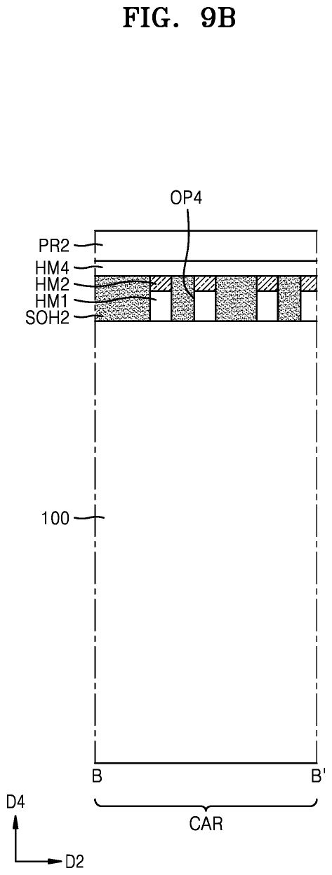

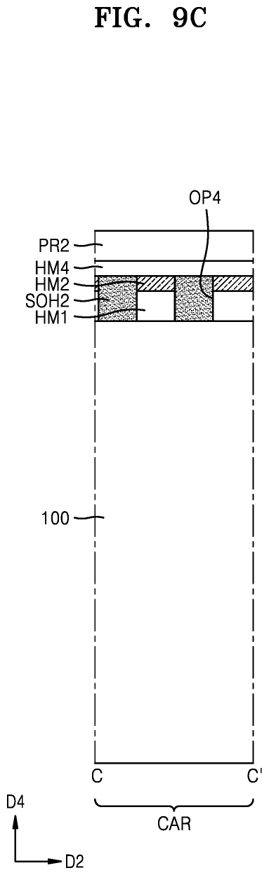

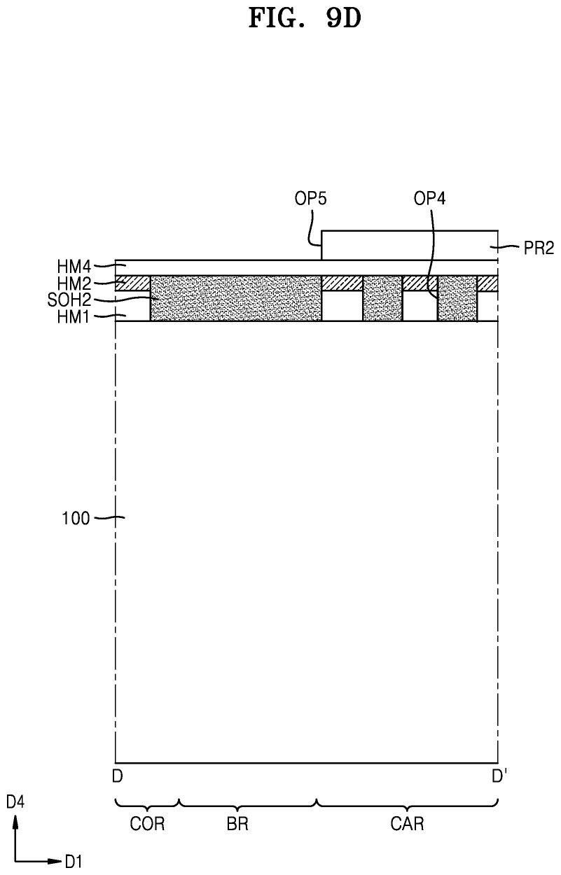

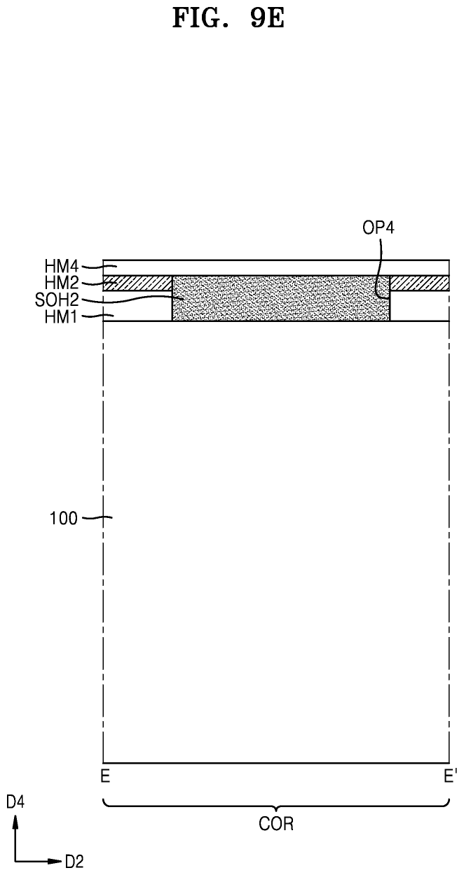

Referring to FIGS. 9A to 9E, a second auxiliary mask SOH2 may be formed in fourth openings OP4. The forming of the second auxiliary mask SOH2 may include forming a second auxiliary mask film (not shown), which is in the fourth openings OP4 and covers or overlaps the top surface of the second hardmask HM2, and performing an etch back process on the second auxiliary mask film. A fourth hardmask HM4 may be formed on the second hardmask HM2 and the second auxiliary mask SOH2. The fourth hardmask HM4 may be formed throughout the cell region CAR, the boundary region BR, and the core region COR.

A second photoresist PR2 may be formed on the fourth hardmask HM4. The second photoresist PR2 may include a fifth opening OP5. The fourth hardmask HM4 may be partially exposed by the fifth opening OP5. The second auxiliary mask SOH2 may include an SOH material. The fourth hardmask HM4 may include silicon oxide. The second photoresist PR2 may include a photoresist material.

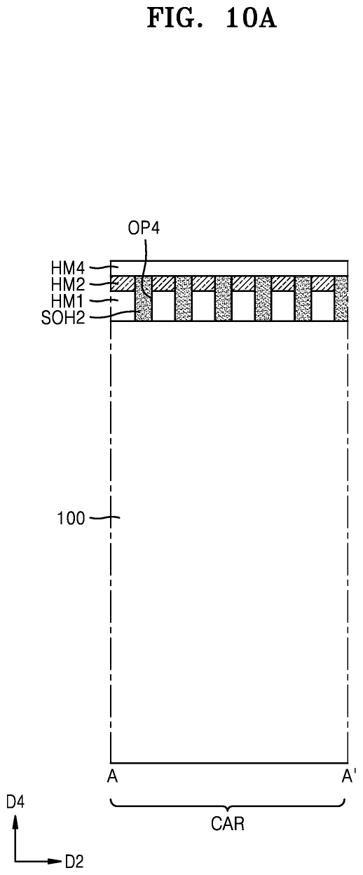

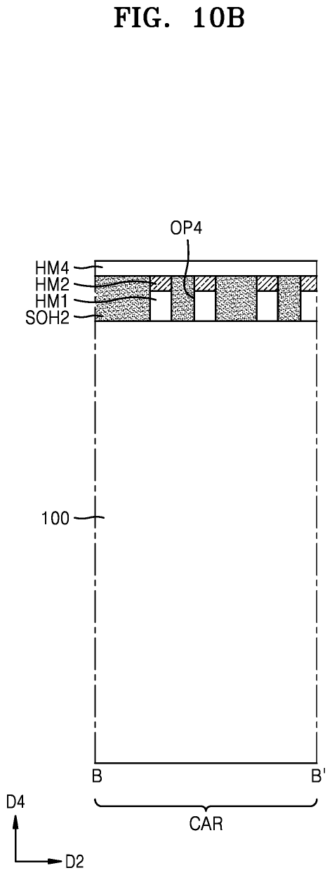

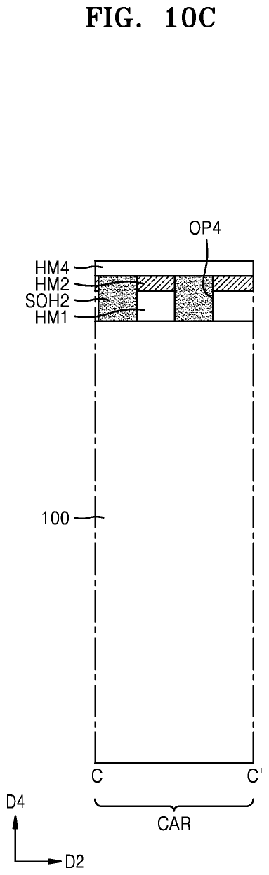

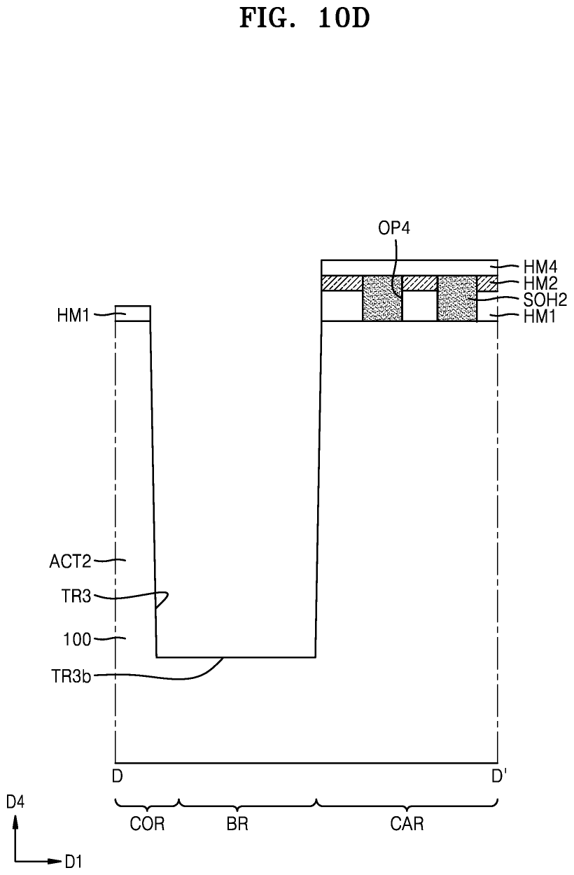

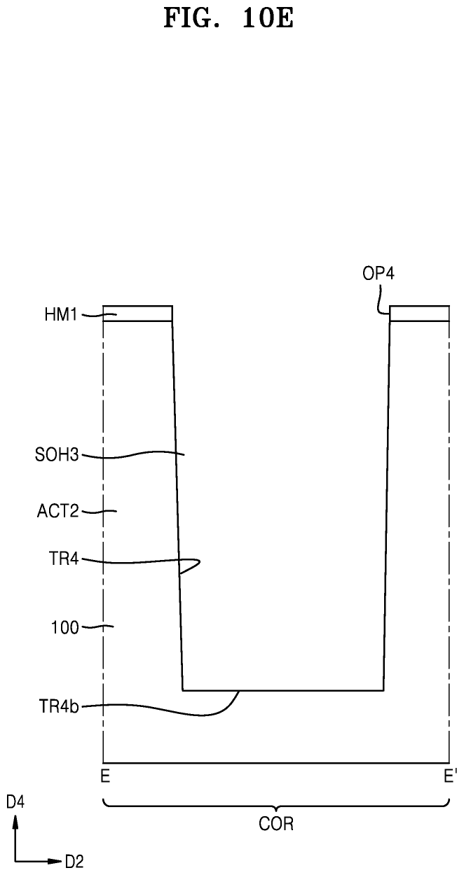

Referring to FIGS. 10A to 10E, a portion of the fourth hardmask HM4 exposed by the fifth opening OP5 may be removed. When the fourth hardmask HM4 is removed, a portion of the second auxiliary mask SOH2 may be exposed. The exposed portion of the second auxiliary mask SOH2 may be removed to partially expose the top surface of the substrate 100 in the boundary region BR and the core region COR. A third trench TR3 and a fourth trench TR4 may be formed by etching the exposed portion of the top surface of the substrate 100 by using the fourth hardmask HM4 as an etch mask. The forming of the third trench TR3 and the fourth trench TR4 may include repeatedly performing a plurality of etch cycles, as described above with reference to FIGS. 4A to 4C. The vertical level of the bottom TR4b of the fourth trench TR4 may be lower than or equal to the vertical level of the bottom TR3b of the third trench TR3. As the third trench TR3 and the fourth trench TR4 are formed, an upper portion of the substrate 100 may be patterned. Accordingly, second active patterns ACT2 may be formed in the core region COR. The third trench TR3 may be formed between a first active pattern ACT1 of the cell region CAR and a second active pattern ACT2 of the core region COR. The third trench TR3 may be formed in the boundary region BR and the core region COR. The fourth trench TR4 may be formed between two core gate structures CGS, which are described below.

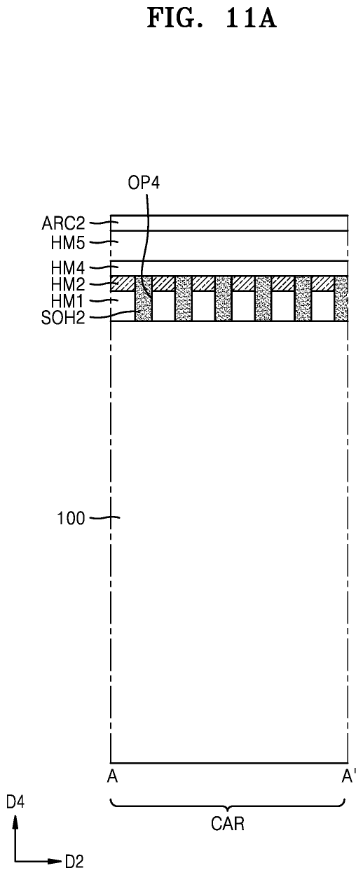

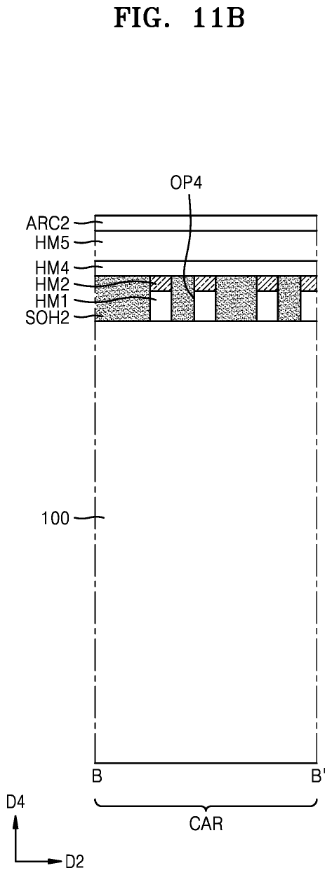

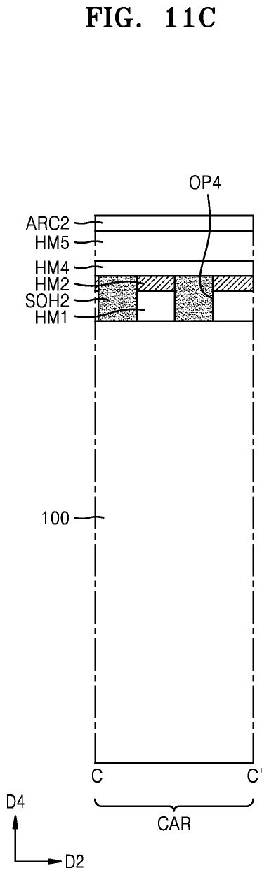

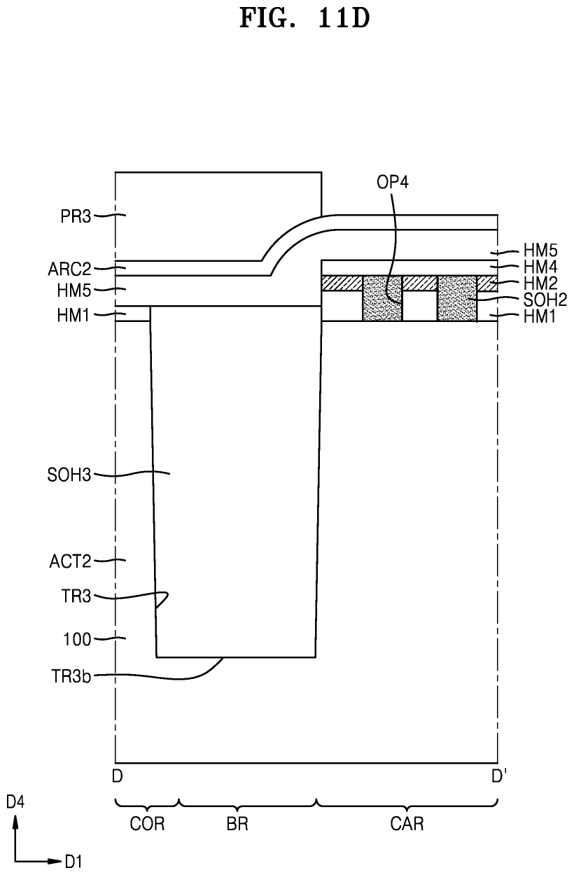

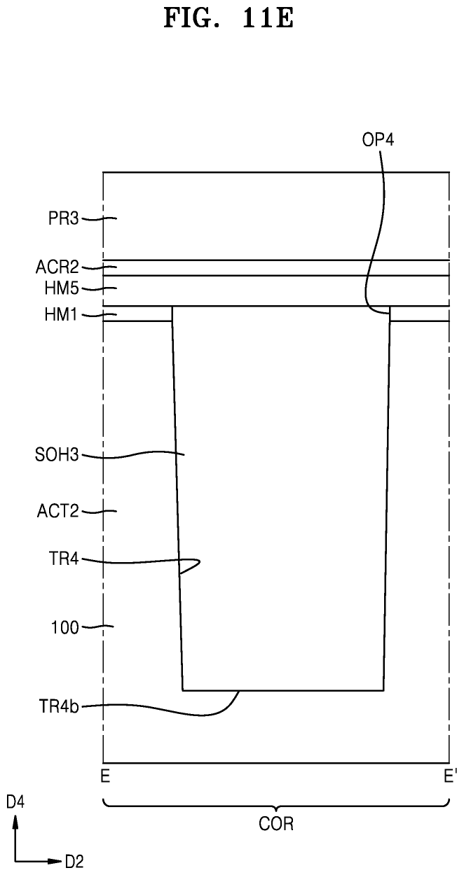

Referring to FIGS. 11A to 11E, a third auxiliary mask SOH3 may be formed in the third trench TR3 and the fourth trench TR4. The forming of the third auxiliary mask SOH3 may include forming a third auxiliary mask film (not shown), which is in the third trench TR3 and the fourth trench TR4 and covers or overlaps the first hardmask HM1 and the fourth hardmask HM4, and performing an etch back process on the third auxiliary mask film. The top surface of the third auxiliary mask SOH3 may be substantially coplanar with the top surface of the first hardmask HM1. Subsequently, a fifth hardmask HM5 may be formed on the first hardmask HM1 and the third auxiliary mask SOH3 in the boundary region BR and the core region COR and on the fourth hardmask HM4 in the cell region CAR. The fifth hardmask HM5 may extend from the cell region CAR to the core region COR via the boundary region BR. The fifth hardmask HM5 may be formed throughout the cell region CAR, the boundary region BR, and the cell region CAR.

A second anti-reflective film ARC2 may be formed on the fifth hardmask HM5. The second anti-reflective film ARC2 may be formed throughout the cell region CAR, the boundary region BR, and the cell region CAR. A third photoresist PR3 may be formed on the second anti-reflective film ARC2. The third photoresist PR3 may be formed only in the boundary region BR and the core region COR. In other words, the third photoresist PR3 may expose the cell region CAR.

The third auxiliary mask SOH3 may include an SOH material. The fifth hardmask HM5 may include silicon oxide. The second anti-reflective film ARC2 may include silicon oxynitride.

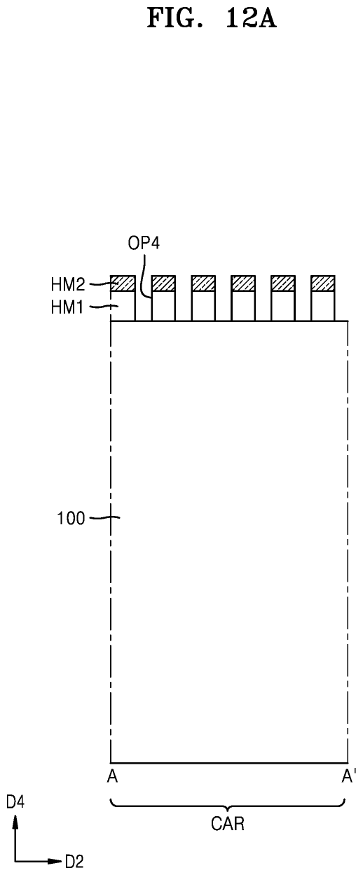

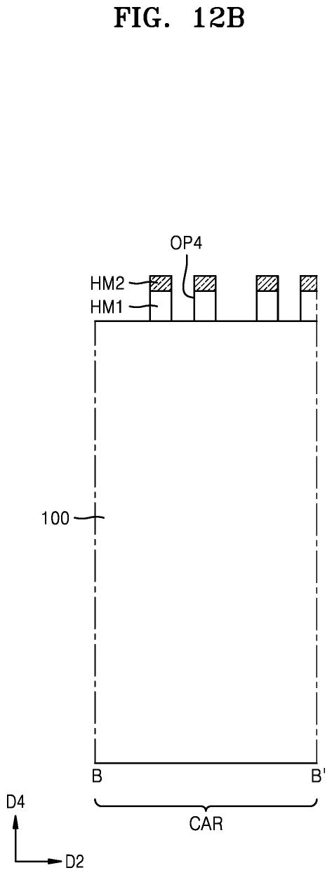

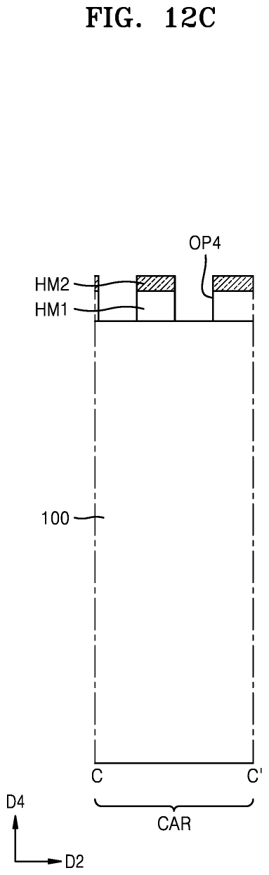

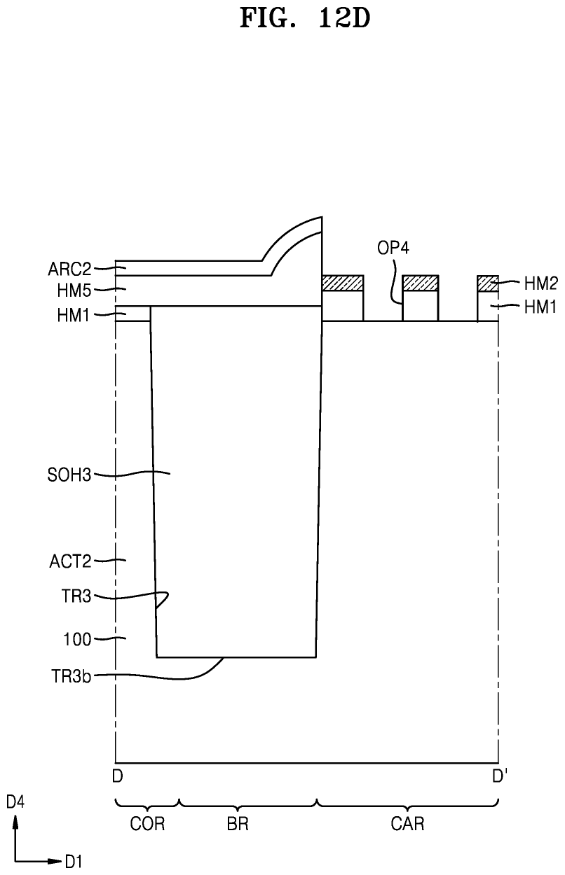

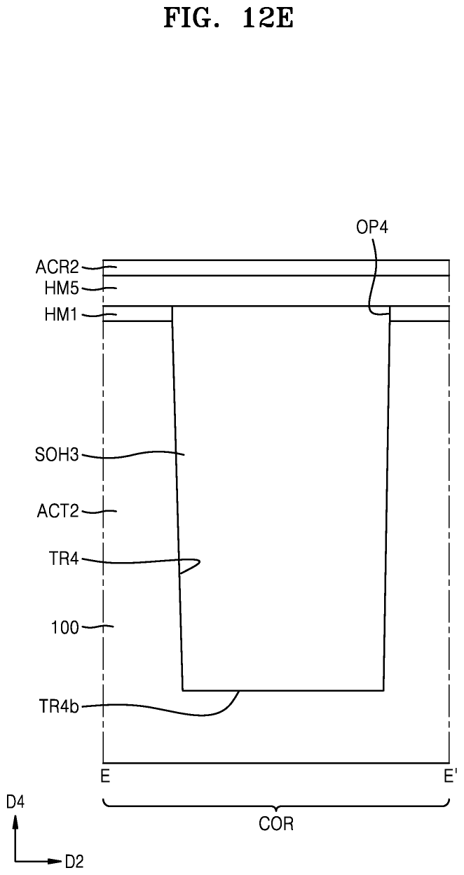

Referring to FIGS. 12A to 12E, the second anti-reflective film ARC2, the fifth hardmask HM5, the fourth hardmask HM4, and the second auxiliary mask SOH2 may be removed from the cell region CAR by using the third photoresist PR3 as an etch mask. The second hardmask HM2 and the first hardmask HM1, which include the fourth openings OP4, may remain in the cell region CAR. The fourth openings OP4 may partially expose the top surface of the substrate 100.

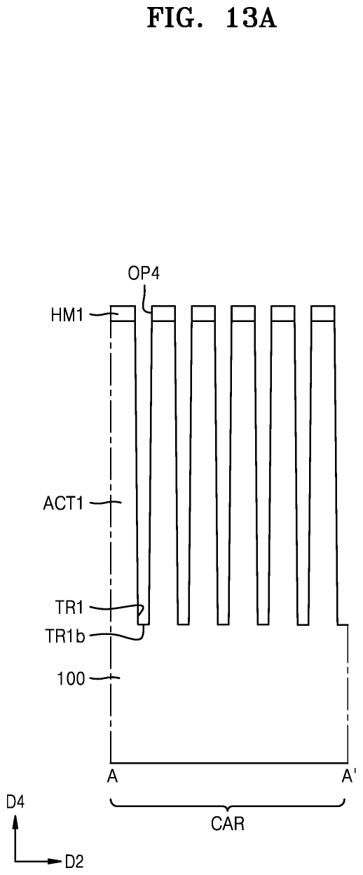

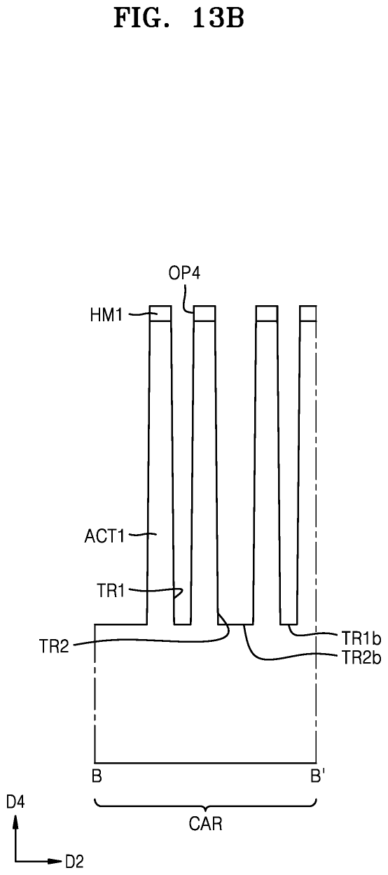

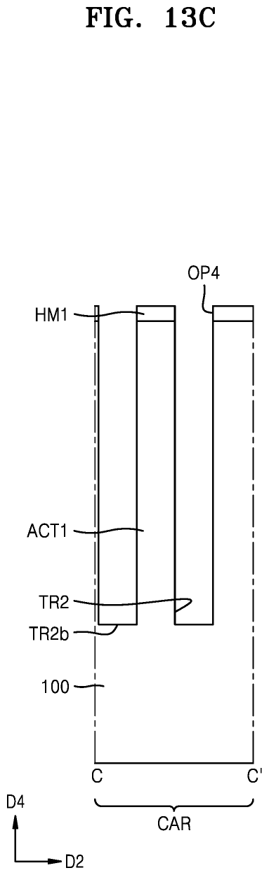

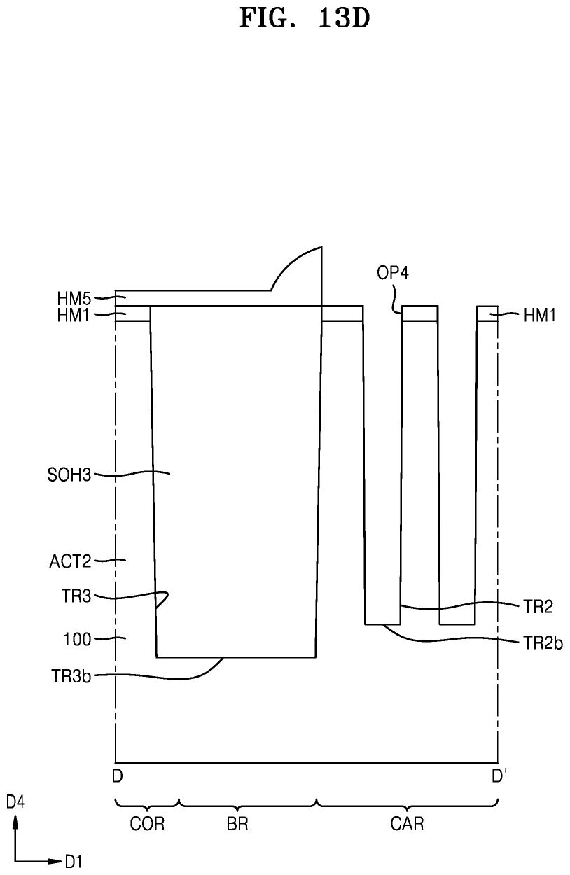

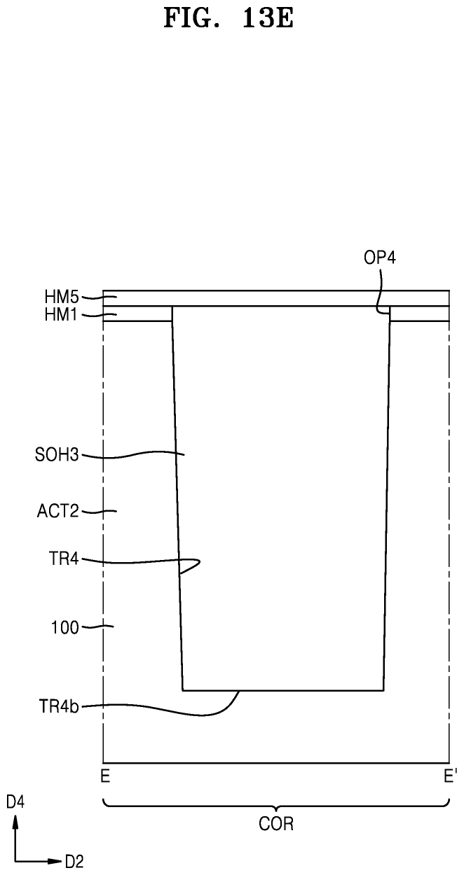

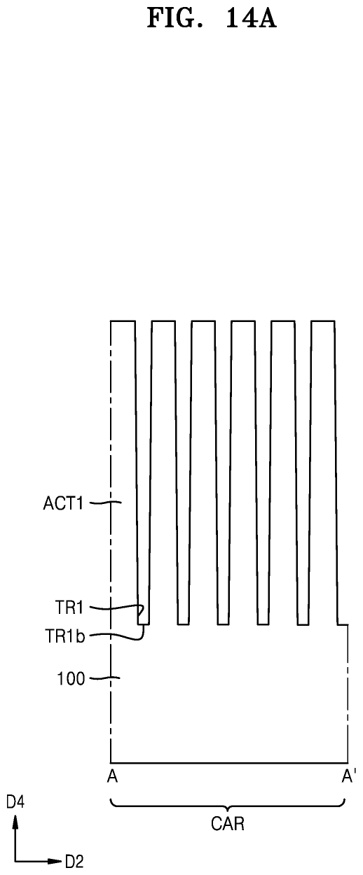

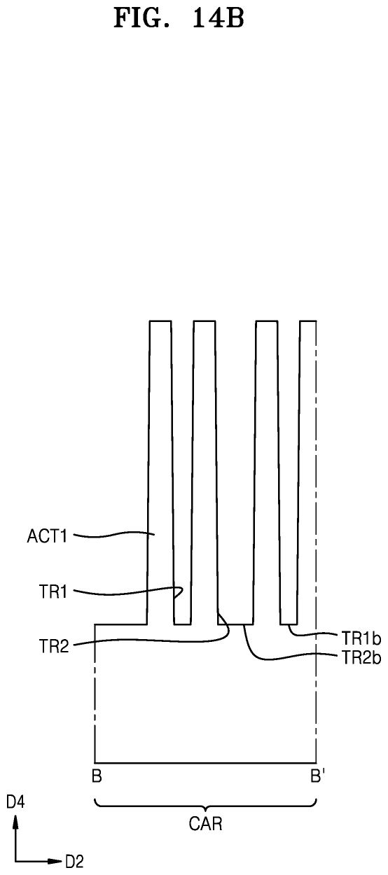

Referring to FIGS. 13A to 13E, a first trench TR1 and a second trench TR2 may be formed by partially etching the top surface of the substrate 100, which is exposed by the fourth openings OP4, by using the second hardmask HM2 and the first hardmask HM1 as etch masks. The forming of the first trench TR1 and the second trench TR2 may include repeatedly performing a plurality of etch cycles, as described above with reference to FIGS. 4A to 4C. The vertical level of the bottom TR1b of the first trench TR1 may be substantially equal to the vertical level of the bottom TR2b of the second trench TR2. The vertical level of the bottom TR3b of the third trench TR3 may be lower than the vertical level of the bottom TR1b of the first trench TR1 and the vertical level of the bottom TR2b of the second trench TR2. The vertical level of the bottom TR4b of the fourth trench TR4 may be lower than the vertical level of the bottom TR1b of the first trench TR1 and the vertical level of the bottom TR2b of the second trench TR2. During the process of forming the first trench TR1 and the second trench TR2, the second hardmask HM2 and the second anti-reflective film ARC2 may be removed.

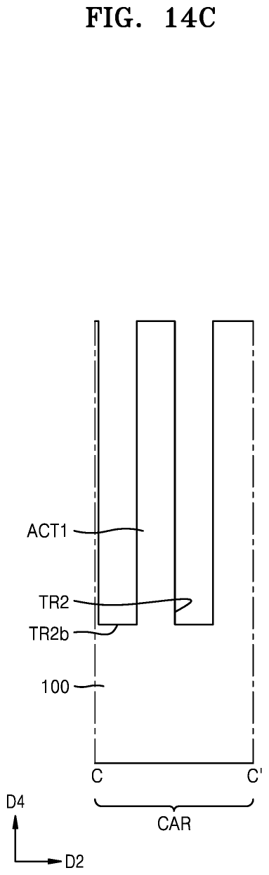

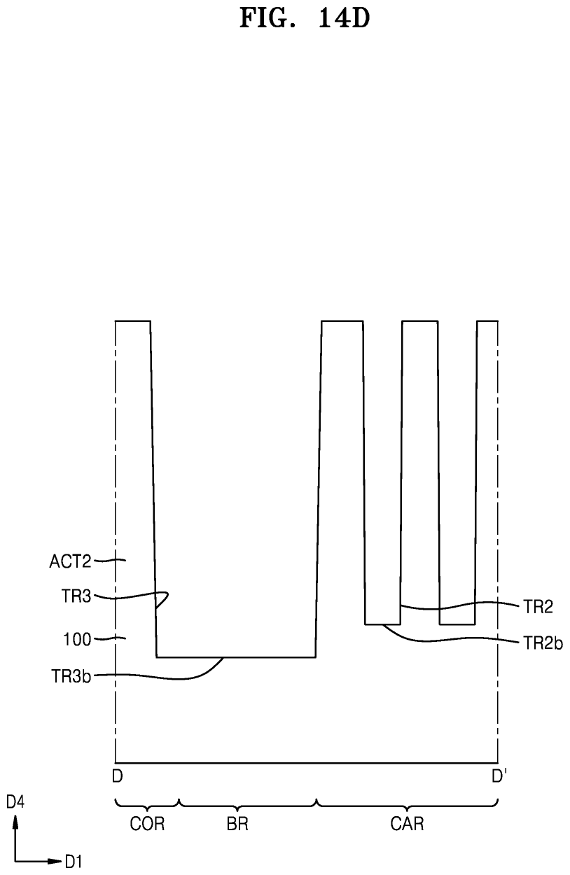

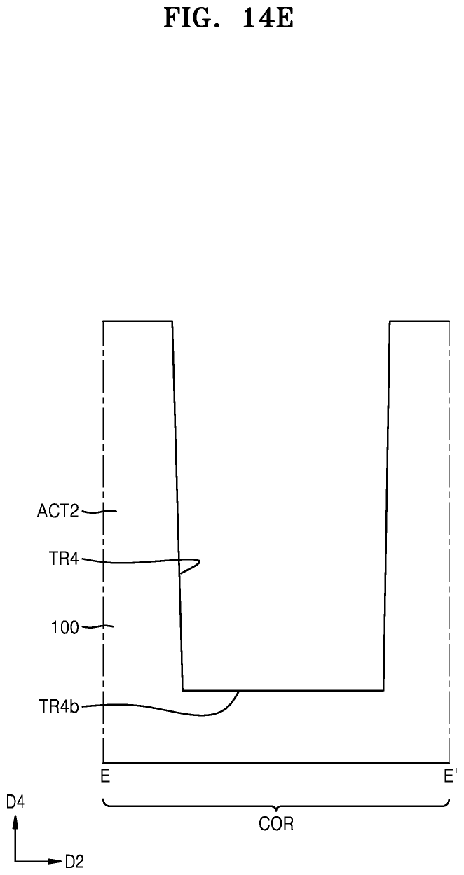

Referring to FIGS. 14A to 14E, the fifth hardmask HM5, the first hardmask HM1, and the third auxiliary mask SOH3 may be removed. As the first trench TR1 and the second trench TR2 are formed, an upper portion of the substrate 100 may be patterned. Accordingly, first active patterns ACT1 may be formed in the cell region CAR.

Each of the first active patterns ACT1 may extend in the third horizontal direction D3 that is parallel with the top surface of the substrate 100. The first active patterns ACT1 may be two-dimensionally arranged in the first horizontal direction D1 and the second horizontal direction D2. The first active patterns ACT1 may be spaced apart from each other in the third horizontal direction D3.

The first and second trenches TR1 and TR2 may be formed among the first active patterns ACT1. The first trench TR1 may be formed between two first active patterns ACT1 adjacent to each other in the second horizontal direction D2. The second trench TR2 may be formed between two first active patterns ACT1 adjacent to each other in the third horizontal direction D3.

In the semiconductor device 10, the width of the first trench TR1 and the width of the second trench TR2 in the cell region CAR may be less than the width of the third trench TR3 in the boundary region BR and the width of the fourth trench TR4 in the core region COR. The depth of the first trench TR1 and the depth of the second trench TR2 may be less than the depth of the third trench TR3 and the depth of the fourth trench TR4. However, when the first trench TR1 and the second trench TR2 are simultaneously formed with the third trench TR3 or the fourth trench TR4, the depth relationship among the first to fourth trenches TR1 to TR4 described above may not be satisfied. This may be because of the characteristics of an etch cycle. When the thickness of a passivation layer is reduced and the amount of etching gas (e.g., Cl₂) in an ME step is increased in an etch cycle, each of the first trench TR1 and the second trench TR2 in the cell region CAR may be etched to a target depth but each of the third trench TR3 in the boundary region BR and the fourth trench TR4 in the core region COR may not be etched to a target depth. In contrast, when the thickness of a passivation layer is increased and the amount of etching gas in an ME step is decreased in an etch cycle, each of the third trench TR3 in the boundary region BR and the fourth trench TR4 in the core region COR may be etched to a target depth but each of the first trench TR1 and the second trench TR2 in the cell region CAR may not be etched to a target depth. Problems occurring when the thickness of a passivation layer is increased and the amount of etching gas in an ME step is decreased in an etch cycle may also occur when the thickness of a passivation layer and the amount of etching gas in an ME step are both increased in an etch cycle. When the thickness of a passivation layer and the amount of etching gas in an ME step are both decreased in an etch cycle, only some of the first to fourth trenches TR1 to TR4 may be etched to a target depth. In other words, when the first to fourth trenches TR1 to TR4 are simultaneously formed, the respective target etching depths of the first to fourth trenches TR1 to TR4 may not be simultaneously satisfied no matter how the process variables of an etch cycle are adjusted.

According to embodiments of the present disclosure, the first trench TR1 and the second trench TR2 in the cell region CAR may be separately formed from the third trench TR3 in the boundary region BR and the fourth trench TR4 in the core region COR. Accordingly, each of the first trench TR1 and the second trench TR2 may be etched to a target depth by reducing the thickness of a passivation layer and increasing the amount of etching gas in an ME step during the formation of the first trench TR1 and the second trench TR2, and each of the third trench TR3 and the fourth trench TR4 may be etched to a target depth by increasing the thickness of a passivation layer and decreasing the amount of etching gas in an ME step during the formation of the third trench TR3 and the fourth trench TR4. In other words, when the first trench TR1 and the second trench TR2 are separately formed from the third and fourth trenches TR3 and TR4, the target etching depths of the first trench TR1 and the second trench TR2 and the target etching depths of the third trench TR3 and the fourth trench TR4 may be simultaneously satisfied. Considering that the first to fourth trenches TR1 to TR4 separate first active patterns ACT1 and second active patterns ACT2 of the semiconductor device 10 from one another, the electrical characteristics and reliability of the semiconductor device 10 may increase due to the reasons described above.

The width of the first trench TR1 and the width of the second trench TR2 may be less than the width of the third trench TR3 and the width of the fourth trench TR4. Accordingly, when the first trench TR1 and the second trench TR2 are formed prior to the third trench TR3 and the fourth trench TR4, bending of a first active pattern ACT1 may occur during a process of forming the third trench TR3 and the fourth trench TR4.

According to embodiments of the present disclosure, after the third trench TR3 is formed in the boundary region BR and the fourth trench TR4 is formed in the core region COR, the first trench TR1 and the second trench TR2 may be formed in the cell region CAR. Accordingly, the bending phenomenon described above may be prevented, and thus, the electrical characteristics and reliability of the semiconductor device 10 may increase.

During the formation of the third trench TR3 and the fourth trench TR4, the process variables of an etch cycle may be adjusted such that an etch amount of a single etch cycle is relatively large. In contrast, the process variables of an etch cycle for the first trench TR1 and the second trench TR2 may be adjusted such that an etch amount of a single etch cycle is relatively small. For those reasons described above, the relationship among the first to fourth heights H1 to H4 described with reference to FIGS. 4A to 4C may be established.

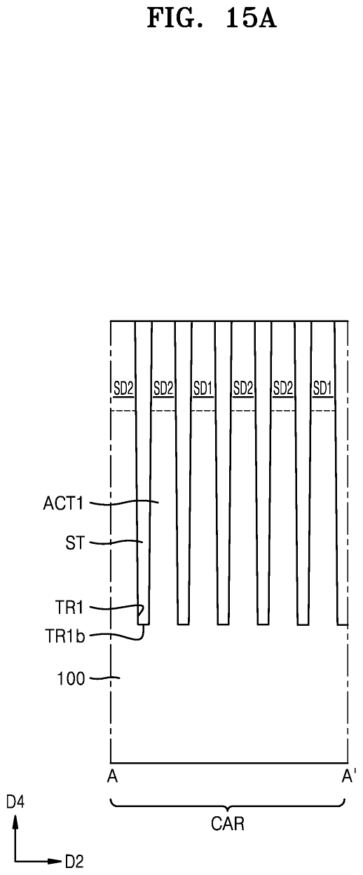

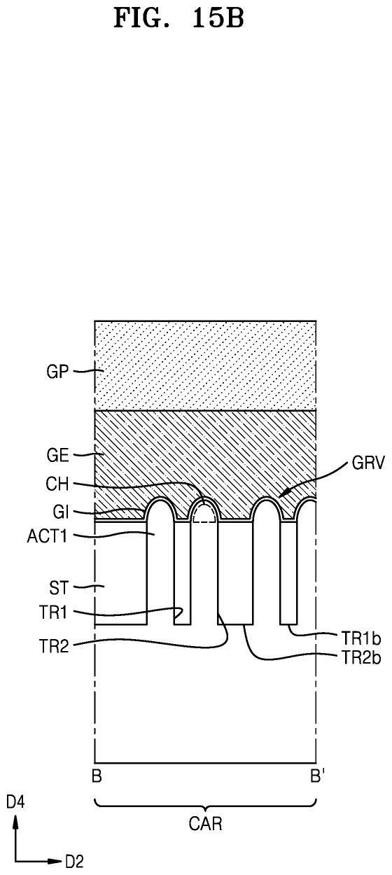

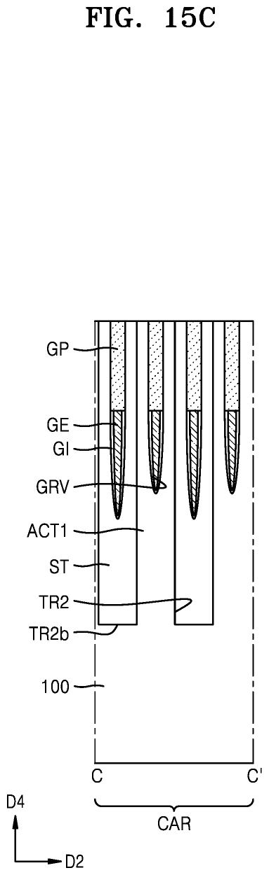

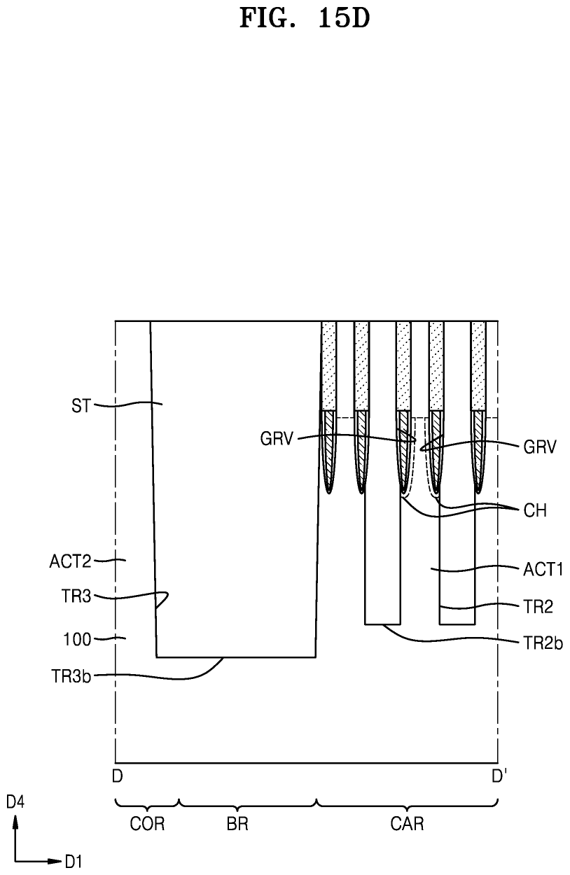

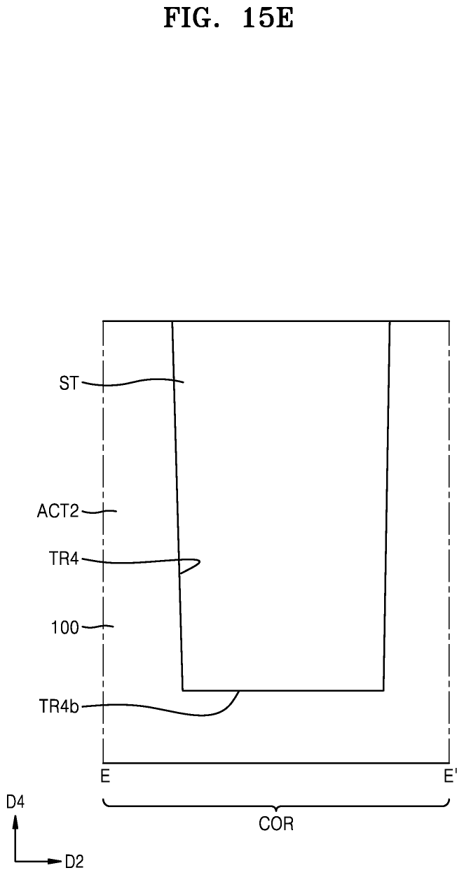

Referring to FIGS. 15A to 15E, an isolation film ST may be formed in the first to fourth trenches TR1 to TR4. The isolation film ST may be formed to be completely in the first to fourth trenches TR1 to TR4 and to overlap or cover the first and second active patterns ACT1 and ACT2. Planarization may be performed on the isolation film ST so that the top surfaces of the first and second active patterns ACT1 and ACT2 are exposed.

Grooves GRV may be formed by patterning the first active patterns ACT1 and the isolation film ST in the cell region CAR. According to a plan view, each of the grooves GRV may have a linear shape extending in the second horizontal direction D2.

The forming of the grooves GRV may include forming a hardmask pattern including openings and etching the exposed portions of the first active patterns ACT1 and the isolation film ST by using the hardmask pattern as an etch mask. The grooves GRV may be shallower than the first trench TR1.

A gate dielectric film GI, a gate electrode GE, and a gate capping film GP may be sequentially formed in each of the grooves GRV. In detail, the gate dielectric film GI may be conformally formed in each of the grooves GRV. The gate dielectric film GI may include a silicon oxide film, a silicon nitride film, a silicon oxynitride film, and/or a high-permittivity material.

The gate electrode GE may be formed by forming a conductive film on the gate dielectric film GI and in each groove GRV. The conductive film may include conductive metal nitride and/or a metal material.

The gate dielectric film GI and the gate electrode GE may be recessed, and the gate capping film GP may be formed on the recessed gate electrode GE. The top surface of the gate capping film GP may be coplanar with the top surface of the first active patterns ACT1.

A first source/drain region SD1 and a pair of second source/drain regions SD2 may be respectively formed in upper portions of respective first active patterns ACT1 by performing ion-implantation on the first active patterns ACT1. The pair of second source/drain regions SD2 may be separated from each other with the first source/drain region SD1 therebetween in the third horizontal direction D3. For example, the first and second source/drain regions SD1 and SD2 may be doped with the same impurities as each other.

A channel region CH may be defined in a first active pattern ACT1 below the gate electrode GE. According to a plan view, the channel region CH may be between the first source/drain region SD1 and a second source/drain region SD2. The gate electrode GE may be formed on the top and opposite sidewalls of the channel region CH.

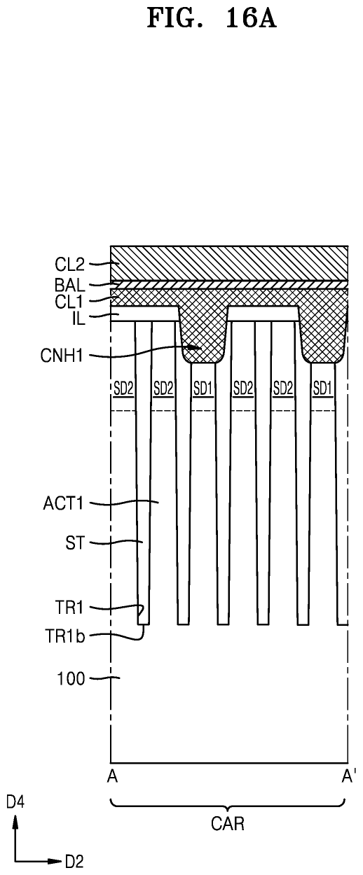

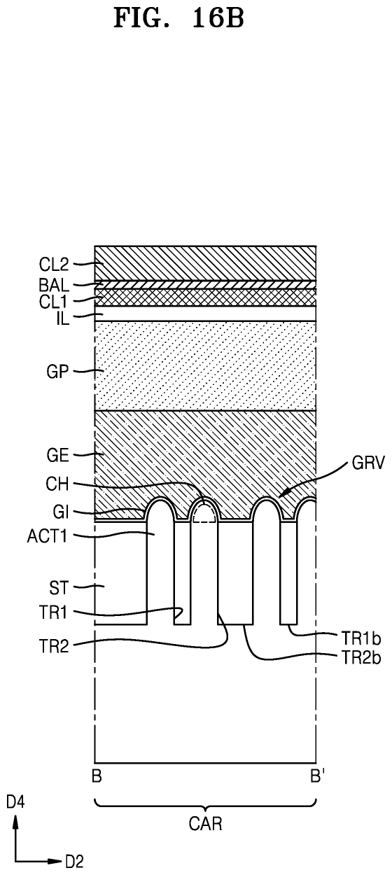

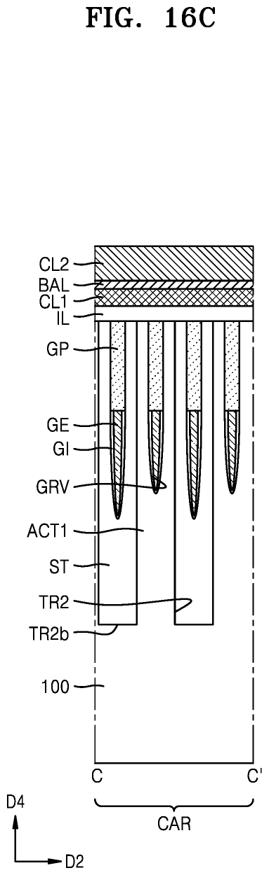

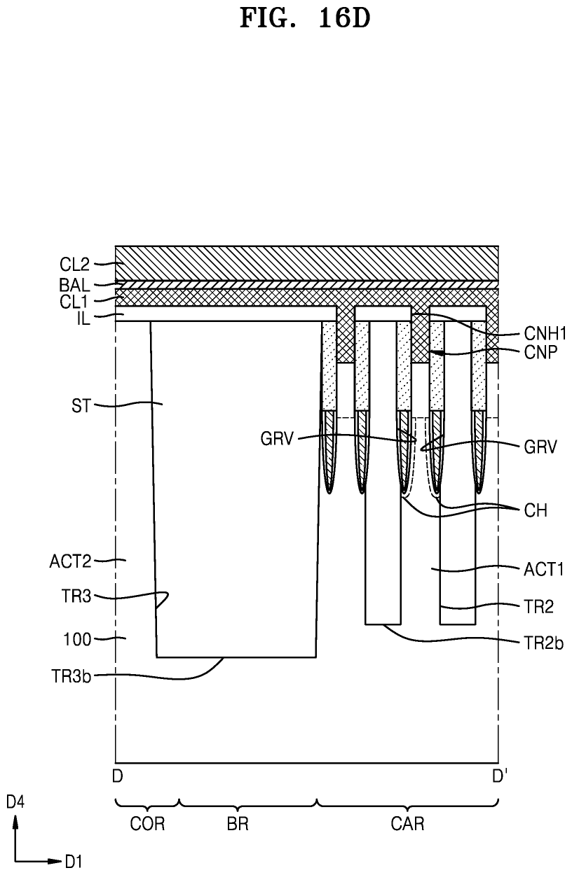

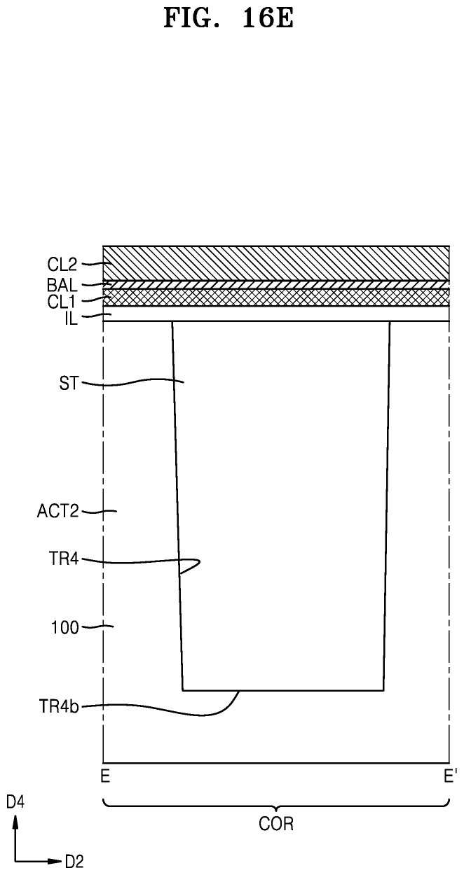

Referring to FIGS. 16A to 16E, a buffer film IL may be formed on the entire surface of the substrate 100. In other words, the buffer film IL may be formed throughout the cell region CAR, the boundary region BR, and the core region COR. For example, the buffer film IL may have a multi-layer structure, in which a silicon oxide film and a silicon oxynitride film are stacked on each other. First contact holes CNH1 respectively exposing first source/drain regions SD1 of respective first active patterns ACT1 may be formed by patterning the buffer film IL of the cell region CAR. When each of the first contact holes CNH1 is formed, an upper portion of a first source/drain region SD1 may be recessed. When each first contact hole CNH1 is formed, an upper portion of the isolation film ST around the first source/drain region SD1 may also be recessed.

A first conductive film CL1, a barrier film BAL, and a second conductive film CL2 may be sequentially formed on the buffer film IL. The first conductive film CL1, the barrier film BAL, and the second conductive film CL2 may be formed throughout the cell region CAR, the boundary region BR, and the core region COR.

The first conductive film CL1 may be in the first contact holes CNH1. In other words, the first conductive film CL1 may be in contact with the first source/drain regions SD1 of the respective first active patterns ACT1. The first conductive film CL1 may be vertically separated from the second source/drain regions SD2 of respective first active patterns ACT1 by the buffer film IL. The first conductive film CL1 may include a doped semiconductor material.

The barrier film BAL may be formed between the first conductive film CL1 and the second conductive film CL2. The barrier film BAL may include conductive metal nitride. The second conductive film CL2 may include a metal material. The barrier film BAL may suppress the metal material of the second conductive film CL2 from diffusing into the first conductive film CL1.

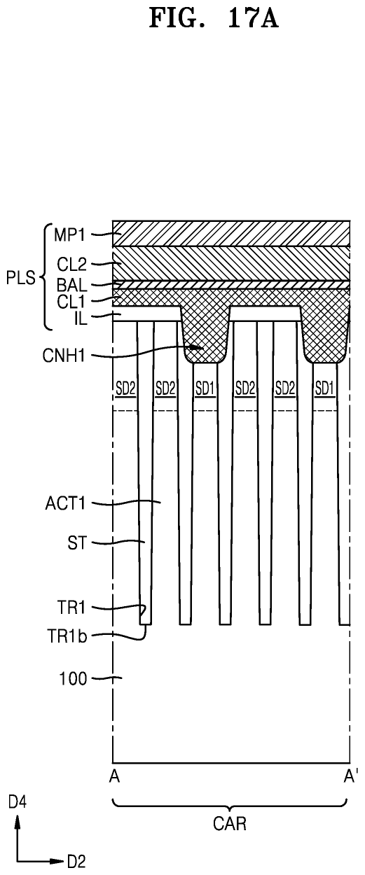

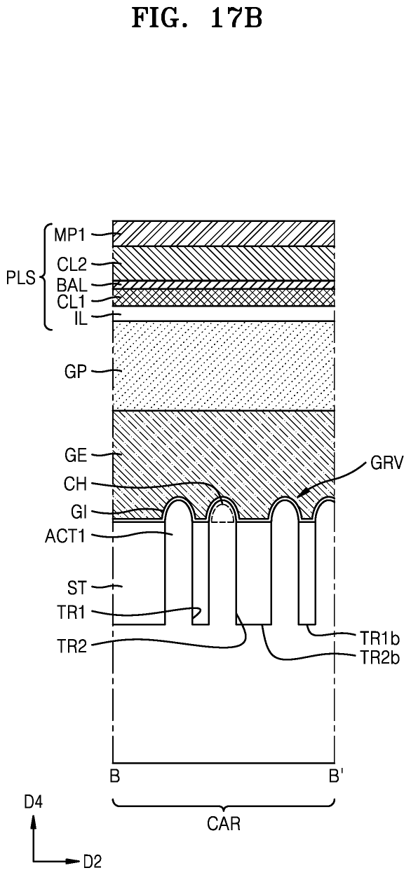

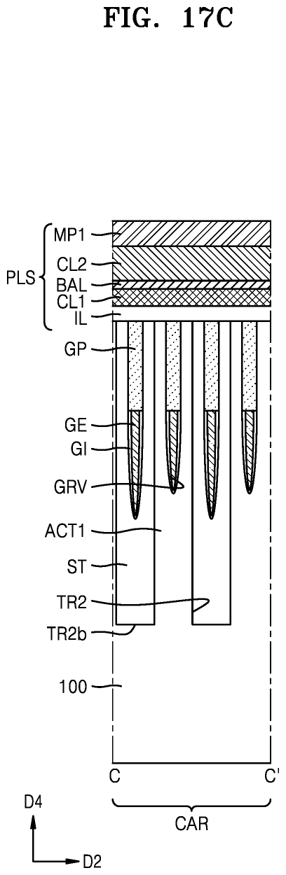

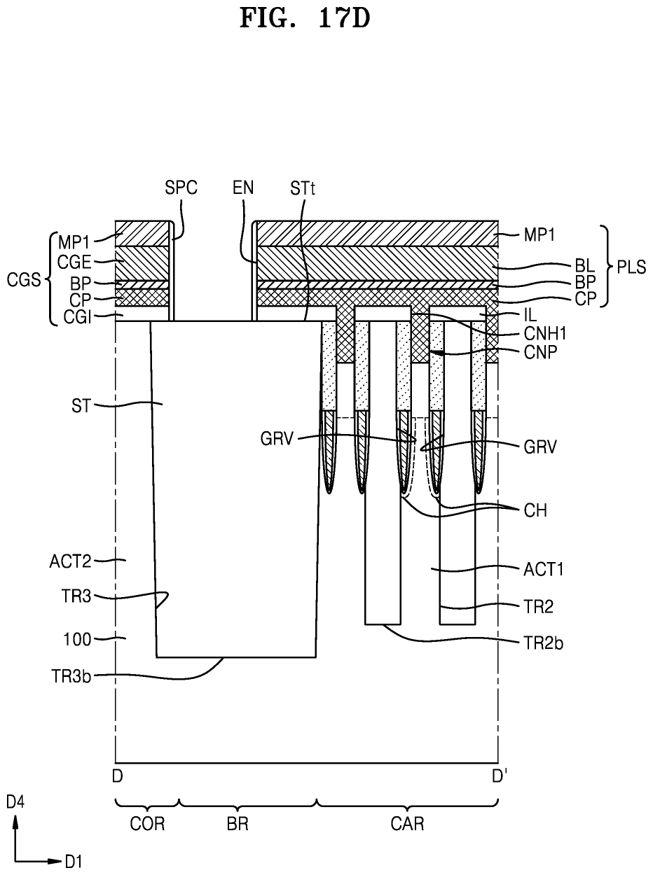

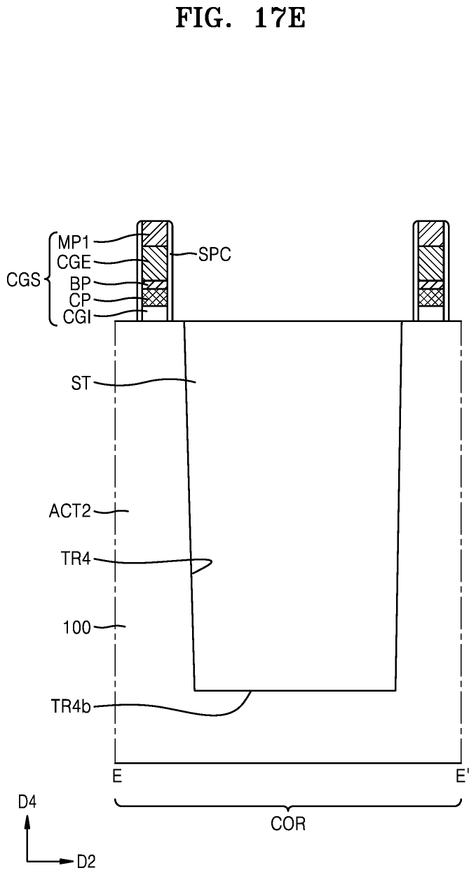

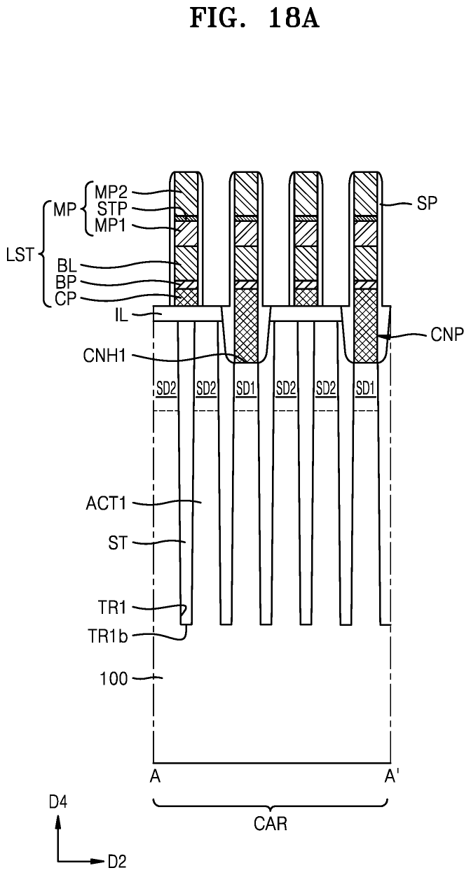

Referring to FIGS. 17A to 17E, a first mask pattern MP1 may be formed on the second conductive film CL2. The first mask pattern MP1 may be formed to completely cover or overlap the cell region CAR. An edge of the first mask pattern MP1 may overlap the boundary region BR. The first mask pattern MP1 of the core region COR may define a core gate structure CGS. In detail, the forming of the first mask pattern MP1 may include forming a first mask film on the second conductive film CL2 and patterning the first mask film by using photolithography.

The second conductive film CL2, the barrier film BAL, the first conductive film CL1, and the buffer film IL, which are below the first mask pattern MP1, may be etched by using the first mask pattern MP1 as an etch mask. Accordingly, a portion of the isolation film ST, which is not covered with or overlapped by the first mask pattern MP1, may be exposed (see FIGS. 17D and 17E).

A plate structure PLS may be formed by patterning the buffer film IL, the first conductive film CL1, the barrier film BAL, and the second conductive film CL2 in the cell region CAR by using the first mask pattern MP1. According to a plan view, the plate structure PLS may have a quadrangular plate shape. The plate structure PLS may entirely overlap the cell region CAR. An edge of the plate structure PLS may overlap at least a portion of the boundary region BR.

The core gate structure CGS may be formed by patterning the buffer film IL, the first conductive film CL1, the barrier film BAL, and the second conductive film CL2 on a second active pattern ACT2 by using the first mask pattern MP1. The core gate structure CGS may include a core gate insulating film CGI, a conductive pattern CP, a barrier pattern BP, a core gate electrode CGE, and the first mask pattern MP1, which are sequentially stacked on the second active pattern ACT2. The fourth trench TR4 may be between two core gate structures CGS. In other words, the fourth trench TR4 may electrically insulate at least two second active patterns ACT2 from each other in the core region COR.

A sidewall spacer SPC may be formed on an end EN (or a sidewall) of the plate structure PLS in the boundary region BR. The sidewall spacer SPC may be formed on a sidewall of the core gate structure CGS. The forming of the sidewall spacer SPC may include forming a spacer film on the entire surface of the substrate 100 and anisotropically etching the spacer film. The sidewall spacer SPC may include silicon oxide.

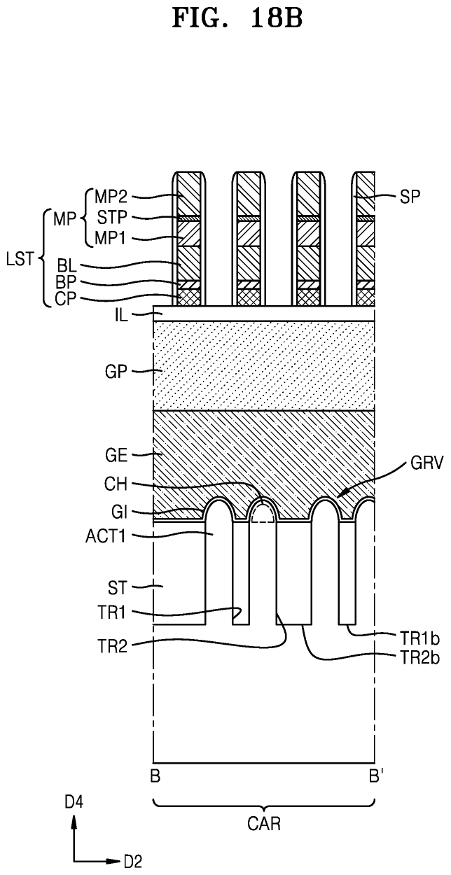

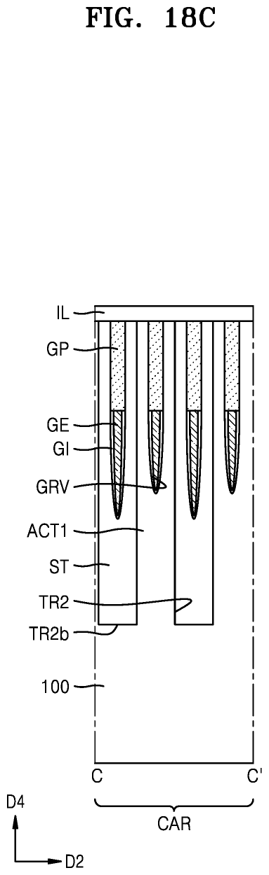

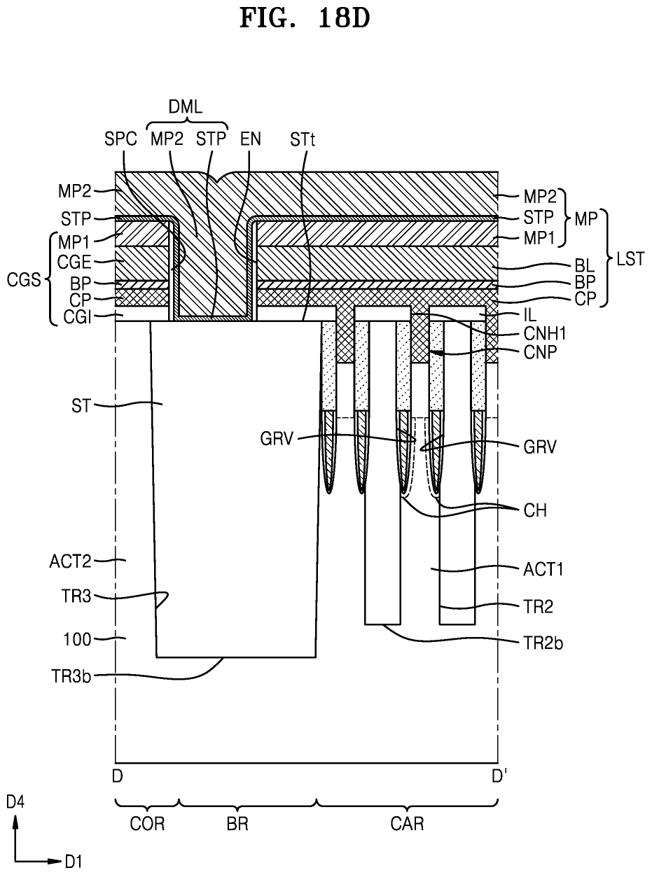

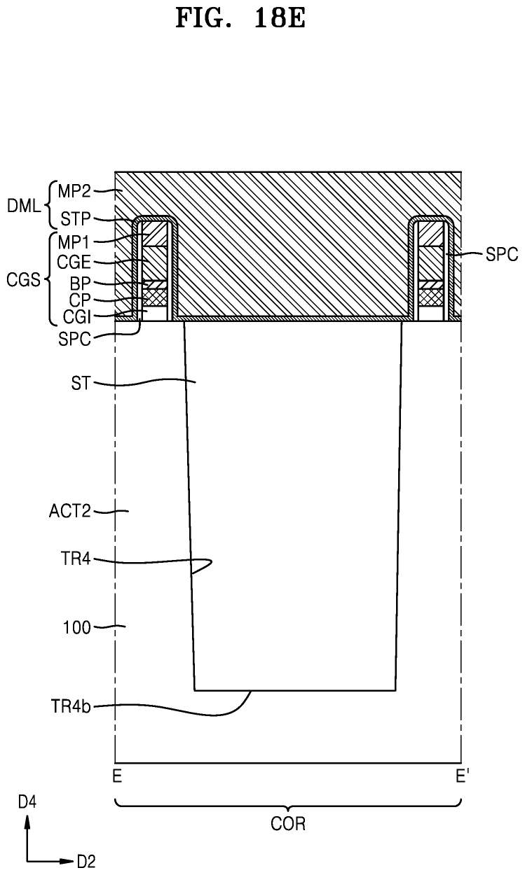

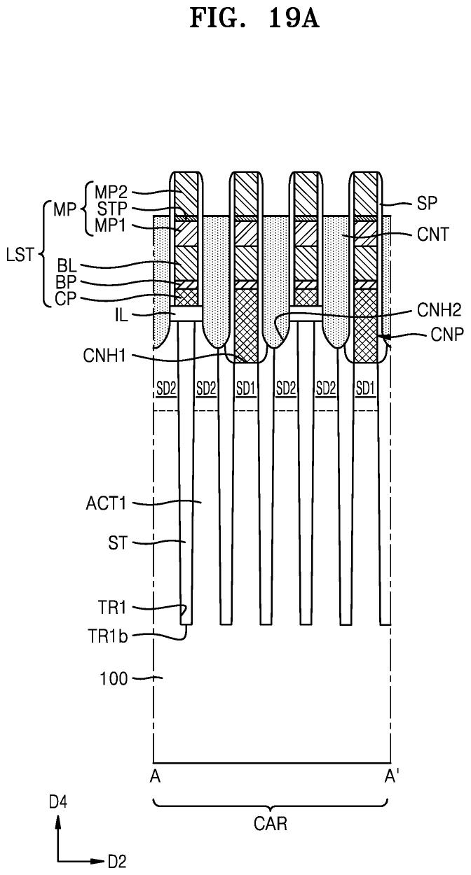

Referring to FIGS. 18A to 18E, the plate structure PLS of the cell region CAR may be patterned to form line structures LST, which extend in the first horizontal direction to be parallel with each other. The line structures LST may extend from the cell region CAR to the boundary region BR. A capping pattern DML may be formed on an end EN of a line structure LST of the boundary region BR.

In detail, the forming of the line structures LST and the capping pattern DML may include forming a stopper film (not shown) and a second mask film (not shown) on the substrate 100, forming a second mask pattern MP2 from the second mask film by using photolithography, and patterning the plate structure PLS by using the second mask pattern MP2 as an etch mask.

A stopper pattern STP, the first mask pattern MP1, a bit line BL, a barrier pattern BP, and a conductive pattern CP may be formed by sequentially patterning the stopper film, the first mask pattern MP1, the second conductive film CL2, the barrier film BAL, and the first conductive film CL1 by using the second mask pattern MP2 of the cell region CAR as an etch mask. The conductive pattern CP, the barrier pattern BP, the bit line BL, and a mask pattern MP, which are sequentially stacked on the buffer film IL of the cell region CAR, may form a line structure LST, wherein the mask pattern MP includes the first mask pattern MP1, the stopper pattern STP, and the second mask pattern MP2. In other words, a plurality of line structures LST may be formed from the plate structure PLS by using the second mask pattern MP2 of the cell region CAR. According to a plan view, each of the bit lines BL may extend crossing gate electrodes GE.

The conductive pattern CP of each line structure LST may include contact portions CNP respectively in the first contact holes CNH1. The conductive pattern CP may be connected to a first source/drain region SD1 through a contact portion CNP. In other words, each bit line BL may be electrically connected to the first source/drain region SD1 through the conductive pattern CP.

The second mask pattern MP2 of the boundary region BR may form the capping pattern DML. The capping pattern DML may cover or overlap the end EN of the line structure LST.

The second mask pattern MP2 of the core region COR may have a plate shape overlapping the entirety of the core region COR. In other words, the second mask pattern MP2 may cover or overlap the top surface of the core gate structure CGS.

A pair of spacers SP may be respectively formed on the opposite sidewalls of the line structure LST. The forming of the spacers SP may include conformally forming a spacer film on the entire surface of the substrate 100 and performing anisotropically etching the spacer film.

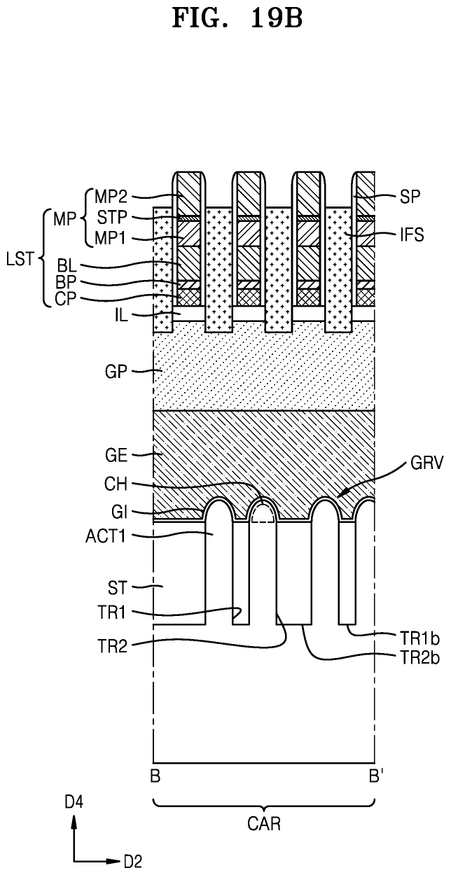

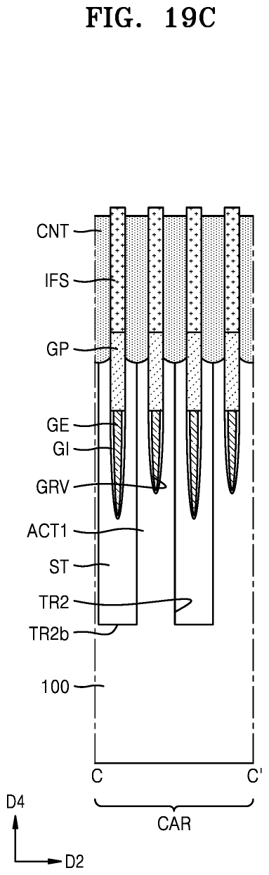

Referring to FIGS. 19A to 19C and FIGS. 18D and 18E, second contact holes CNH2 may be formed to respectively expose second source/drain regions SD2 by performing an etching process on the substrate 100 by using the spacers SP and mask patterns MP as etch masks. In detail, the second contact holes CNH2 may extend below the top surface of the substrate 100 through the buffer film IL. When each of the second contact holes CNH2 is formed, an upper portion of a second source/drain region SD2 may be recessed. When each second contact hole CNH2 is formed, an upper portion of the isolation film ST around the second source/drain region SD2 may also be recessed.

A plurality of insulating fences IFS may be formed between two adjacent line structures LST. The insulating fences IFS may not overlap the second contact holes CNH2 and may expose the second contact holes CNH2.

Contacts CNT may be respectively formed in the second contact holes CNH2 by at least partially or completely filling the second contact holes CNH2 with a conductive material. The contact CNT may be respectively connected to the second source/drain regions SD2. In detail, after the conductive material is formed on the entire surface of the substrate 100, the conductive material may be recessed such that the top surface of the conductive material is lower than the top surface of the insulating fences IFS. Accordingly, the conductive material may be separated by the insulating fences IFS into the contacts CNT respectively in the second contact holes CNH2. The contacts CNT and the insulating fences IFS may be between two adjacent line structures LST and may alternate with each other in the first horizontal direction D1.

The conductive material at least partially or completely filling the second contact holes CNH2 may include a doped semiconductor material. For example, the conductive material may include doped polysilicon. The second contact holes CNH2 may be at least partially or completely filled with a doped semiconductor and impurities in the semiconductor may be diffused into the second source/drain regions SD2. The impurities may be diffused using a metallurgical process.

The conductive material in a second contact hole CNH2 of the boundary region BR may form a dummy contact DCNT. The dummy contact DCNT may correspond to a dummy that is in contact with an upper portion of the isolation film ST.

Referring back to FIGS. 3A to 3E, a landing pad LP may be formed on each of the contacts CNT of the cell region CAR. In detail, a metal film may be formed on the contacts CNT and the insulating fences IFS. A plurality of landing pads LP may be formed by patterning the metal film. An insulating pattern INP may be formed by at least partially or completely filling a space between two adjacent landing pads LP with an insulating material.

Data storage elements DS may be respectively formed on the landing pads LP. The forming of each of the data storage elements DS may include forming a lower electrode on a landing pad LP, forming a dielectric film covering, on, or overlapping the lower electrode, and forming an upper electrode on the dielectric film. Although not shown, wiring layers stacked on the data storage elements DS may be formed.

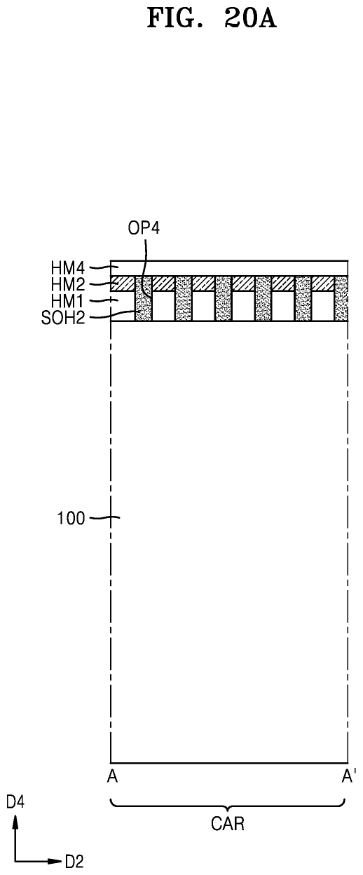

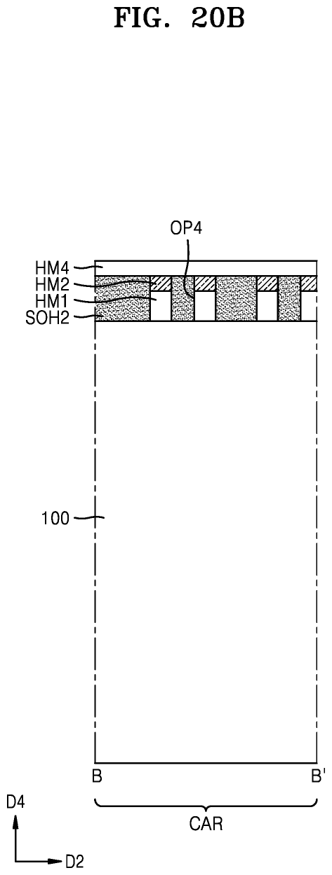

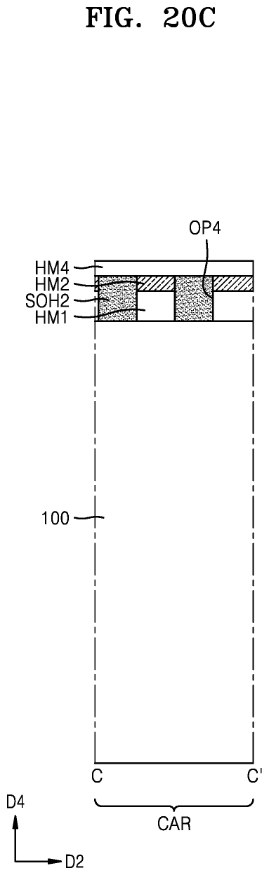

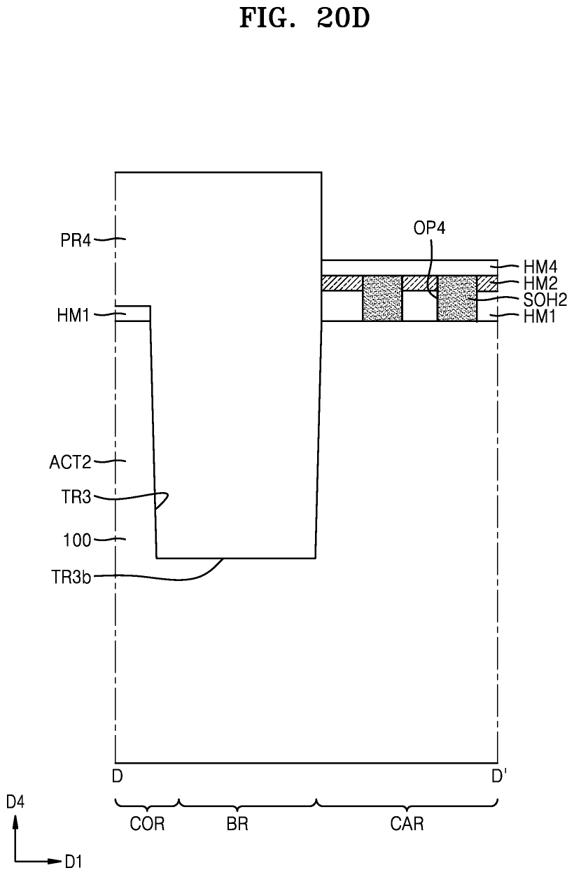

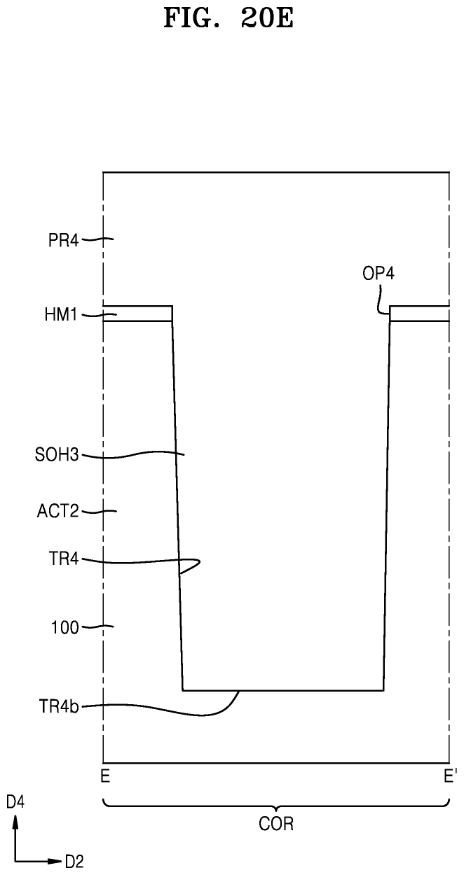

FIGS. 20A to 22E are diagrams illustrating a method of manufacturing a semiconductor device according to some embodiments. In detail, FIGS. 20A, 21A, and 22A are cross-sectional views taken along line A-A′ in FIG. 2. FIGS. 20B, 21B, and 22B are cross-sectional views taken along line B-B′ in FIG. 2. FIGS. 20C, 21C, and 22C are cross-sectional views taken along line C-C in FIG. 2. FIGS. 20D, 21D, and 22D are cross-sectional views taken along line D-D′ in FIG. 2. FIGS. 20E, 21E, and 22E are cross-sectional views taken along line E-E′ in FIG. 2.

Hereinafter, according to some embodiments, a method of manufacturing the semiconductor device 10 is described with reference to FIGS. 20A to 22E.

FIGS. 20A to 20E may illustrate the resultant structure of the manufacturing processes described with reference to FIGS. 5A to 9E. A portion of the fourth hardmask HM4 exposed by the fifth opening OP5 may be removed. When the fourth hardmask HM4 is removed, a portion of the second auxiliary mask SOH2 may be exposed. A portion of the top surface of the substrate 100 in the boundary region BR and the core region COR may be exposed by removing the exposed portion of the second auxiliary mask SOH2. A third trench TR3 and a fourth trench TR4 may be formed by partially etching the top surface of the substrate 100 by using the fourth hardmask HM4 as an etch mask. The forming of the third trench TR3 and the fourth trench TR4 may include repeatedly performing a plurality of etch cycles, as described above with reference to FIGS. 4A to 4C. The vertical level of a bottom TR4b of the fourth trench TR4 may be lower than or equal to the vertical level of the bottom TR3b of the third trench TR3. At this time, the vertical level of the bottom TR3b of the third trench TR3 and the vertical level of the bottom TR4b of the fourth trench TR4 may be respectively higher than the vertical level of the bottom TR3b of the third trench TR3 and the vertical level of the bottom TR4b of the fourth trench TR4 in FIGS. 10A to 10E. In other words, each of the third trench TR3 and the fourth trench TR4 may not be etched to a target depth but may only be partially formed.

Thereafter, a fourth photoresist PR4 may be formed to fill or be in the third trench TR3 and the fourth trench TR4. The fourth photoresist PR4 may be formed throughout the boundary region BR and the core region COR. In other words, the fourth photoresist PR4 may expose the fourth hardmask HM4 in the cell region CAR.

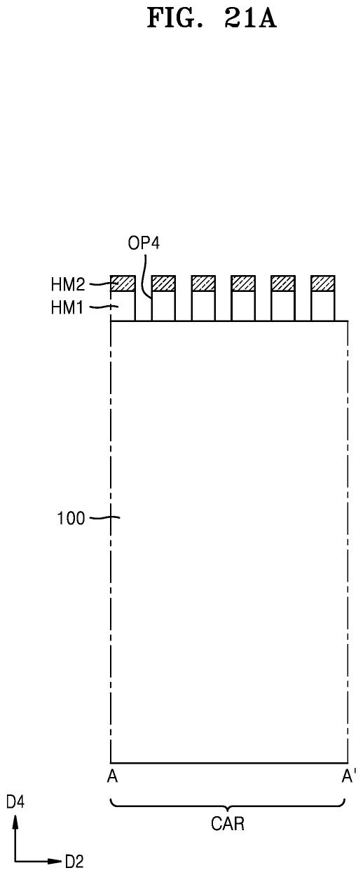

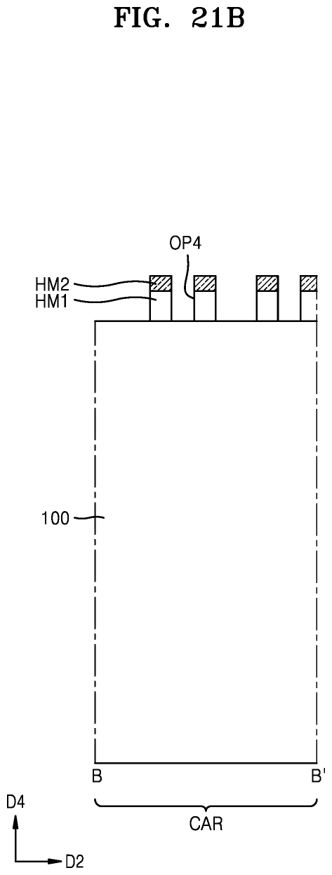

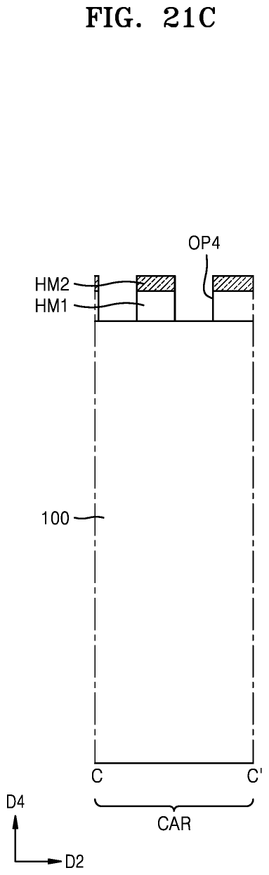

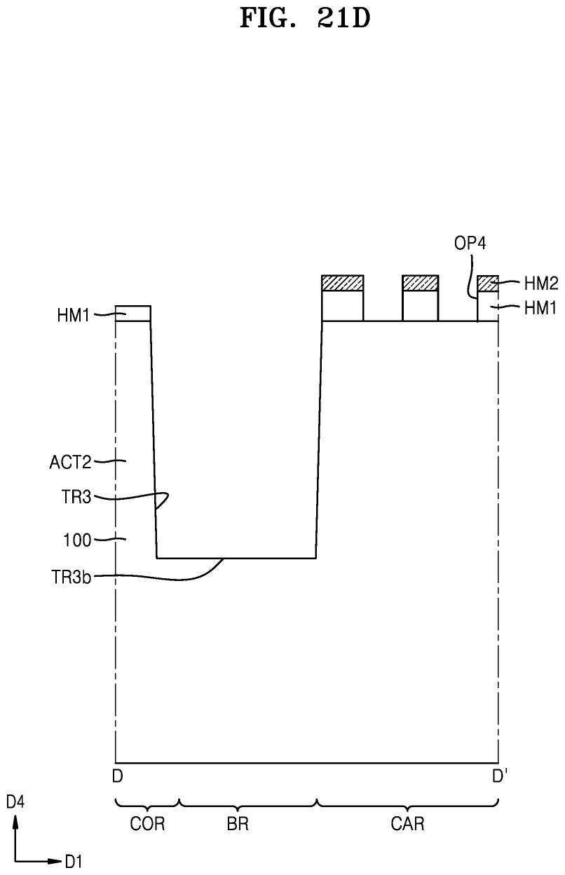

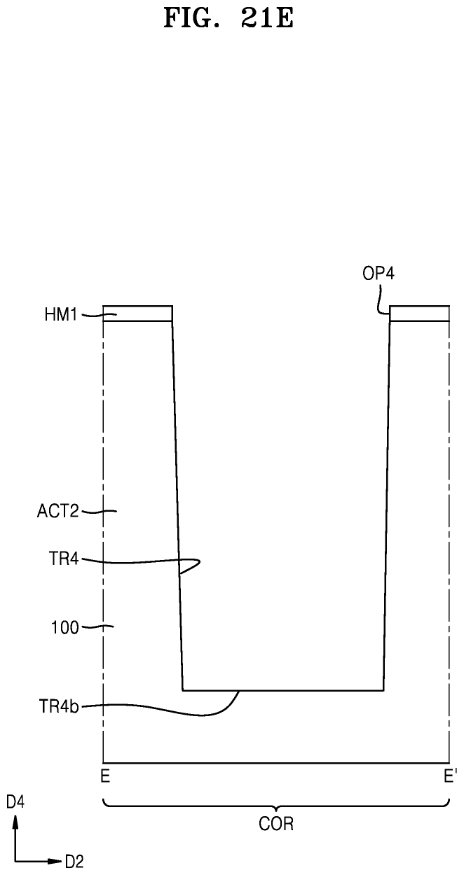

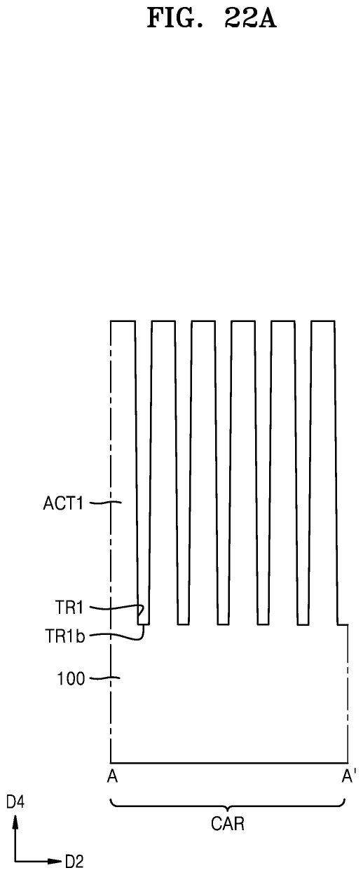

Referring to FIGS. 21A to 21E, the fourth photoresist PR4, the fourth hardmask HM4, and the second auxiliary mask SOH2 may be removed. The top surface of the substrate 100 may be partially exposed by the fourth openings OP4. The bottom TR3b of the third trench TR3 and the bottom TR4b of the fourth trench TR4 may also be exposed.

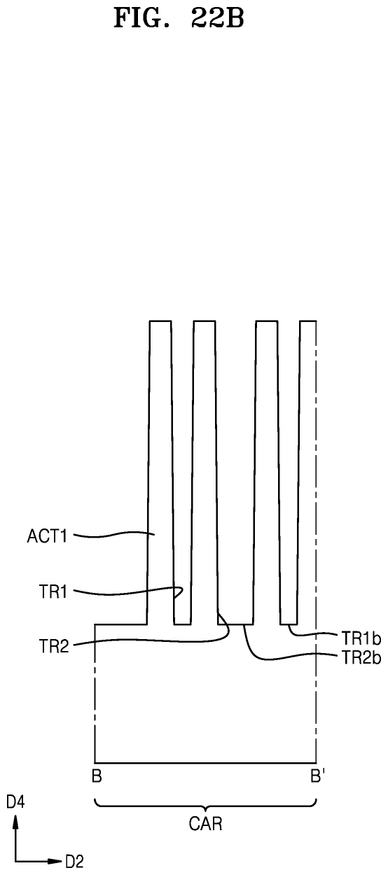

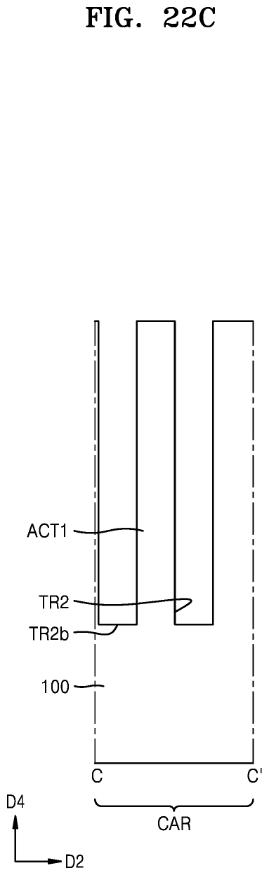

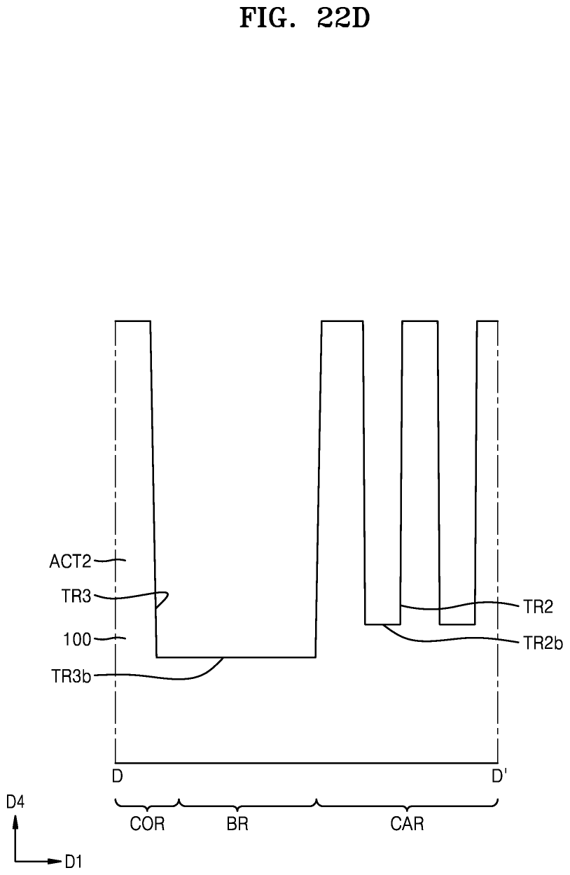

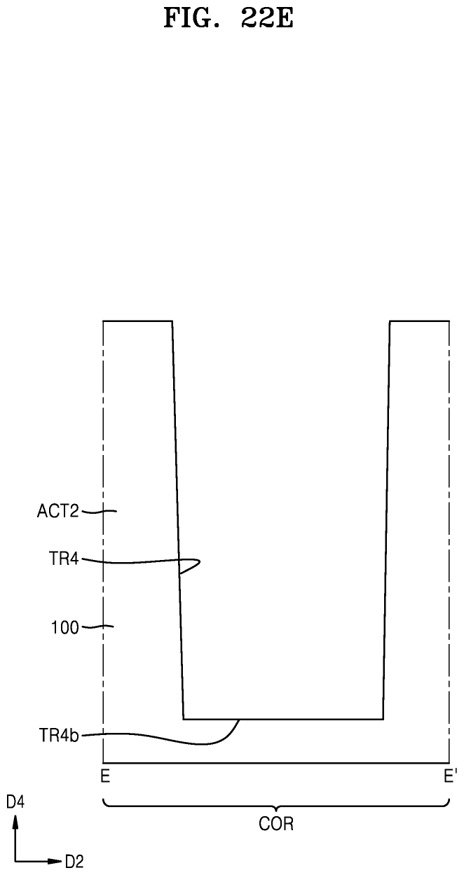

Referring to FIGS. 22A to 22A, first and second trenches TR1 and TR2 may be formed by performing an etching process on the substrate 100. Simultaneously, the third trench TR3 and the fourth trench TR4 may be further etched. Accordingly, the vertical level of the bottom TR3b of the third trench TR3 and the vertical level of the bottom TR4b of the fourth trench TR4 may be respectively lower than the vertical level of the bottom TR3b of the third trench TR3 and the vertical level of the bottom TR4b of the fourth trench TR4 in FIGS. 21A to 21E. The etching process may include repeatedly performing a plurality of etch cycles.

The third trench TR3 and the fourth trench TR4 may be partially formed first, as described with reference to FIGS. 21A to 21E, and then additionally etched while the first and second trenches TR1 and TR2 are being formed, as described with reference to FIGS. 22A to 22E. At this time, during the partial formation of the third trench TR3 and the fourth trench TR4, the process variables of an etch cycle may be adjusted such that an etch amount of a single etch cycle is large. During the additional etching of the third trench TR3 and the fourth trench TR4 and the formation of the first and second trenches TR1 and TR2, the process variables of an etch cycle may be adjusted such that an etch amount of a single etch cycle is small. In this case, as described above with reference to FIGS. 4D and 4E, the inner sidewall of the third trench TR3 may include third recesses SG3 and fifth recesses SG5 and the inner sidewall of the fourth trench TR4 may include fourth recesses SG4 and sixth recesses SG6.

As the first to fourth trenches TR1 to TR4 are formed, an upper portion of the substrate 100 may be patterned. Accordingly, first active patterns ACT1 may be formed in the cell region CAR and second active patterns ACT2 may be formed in the core region COR.

Thereafter, the manufacturing processes described with reference to FIGS. 15A to 19C may be performed on the resultant structure of FIGS. 22A to 22E, thereby manufacturing the semiconductor device 10.

In a method of manufacturing the semiconductor device 10, according to some embodiments of the present disclosure, the first trench TR1 and the second trench TR2 may be formed after the third trench TR3 and the fourth trench TR4 are partially formed. During the formation of the first trench TR1 and the second trench TR2, the third trench TR3 and the fourth trench TR4 may be further etched to be completely formed. Because the third trench TR3 and the fourth trench TR4 in the boundary region BR and the core region COR are partially formed first, the first to fourth trenches TR1 to TR4 may be completely formed simultaneously to respectively have target etch depths. Accordingly, the electrical characteristics and reliability of the semiconductor device 10 may increase.

While the present disclosure has been particularly shown and described with reference to embodiments thereof, it will be understood that various changes in form and details may be made therein without departing from the spirit and scope of the following claims.

What is claimed is:

1. A semiconductor device comprising:
a substrate that comprises a cell region, a core region, and a boundary region between the cell region and the core region, wherein the substrate comprises at least one first active pattern in the cell region and a second active pattern in the core region;
a first trench defined by the at least one first active pattern; and
a second trench defined by the second active pattern,
wherein an inner sidewall of the first trench defines first recesses that extend into the at least one first active pattern, wherein the first recesses are spaced apart from each other in a vertical direction that intersects a top surface of the substrate,
wherein an inner sidewall of the second trench defines second recesses that extend into the second active pattern, wherein the second recesses are spaced apart from each other in the vertical direction,
wherein a distance between two adjacent first recesses from among the first recesses in the vertical direction corresponds to a first height,
wherein a distance between two adjacent second recesses from among the second recesses in the vertical direction corresponds to a second height, and
wherein the second height is greater than the first height.

2. The semiconductor device of claim 1, further comprising:
a third trench that is defined by the at least one first active pattern and comprising a width that is greater than a width of the first trench,
wherein an inner sidewall of the third trench defines third recesses that extend into the at least one first active pattern, wherein the third recesses are spaced apart from each other in the vertical direction,
a distance between two adjacent third recesses from among the third recesses in the vertical direction corresponds to a third height, and
the third height is substantially equal to the first height.

3. The semiconductor device of claim 1, wherein:
the at least one first active pattern comprises a plurality of first active patterns,
the plurality of first active patterns are spaced apart in a first horizontal direction and a second horizontal direction, wherein the first horizontal direction is parallel with the top surface of the substrate, and wherein the second horizontal direction is parallel with the top surface of the substrate and perpendicular to the first horizontal direction,
each of the plurality of first active patterns comprises a long axis in a third horizontal direction that is parallel with the top surface of the substrate and intersects the first horizontal direction and the second horizontal direction,
the first trench is between a first adjacent pair of first active patterns in the second horizontal direction from among the plurality of first active patterns, and
a third trench is between a second adjacent pair of first active patterns in the third horizontal direction from among the plurality of first active patterns.

4. The semiconductor device of claim 1, further comprising:
a third trench that is in the boundary region and between the at least one first active pattern and the second active pattern,
wherein an inner sidewall of the third trench defines third recesses that extend into the at least one first active pattern or the second active pattern, wherein the third recesses are spaced apart from each other in the vertical direction,
a distance between two adjacent third recesses from among the third recesses in the vertical direction corresponds to a third height, and
the third height is greater than the first height.

5. The semiconductor device of claim 4, wherein the third height is substantially equal to the second height.

6. The semiconductor device of claim 4, wherein a bottom of the second trench is a second distance from the substrate, wherein a bottom of the third trench is a third distance from the substrate, and wherein the second distance is less than or equal to the third distance.

7. The semiconductor device of claim 4, further comprising:
an isolation film in the third trench; and
a capping pattern that overlaps at least a portion of a top surface of the isolation film,
wherein the capping pattern extends from the cell region to the core region through the boundary region.

8. The semiconductor device of claim 4, wherein a width of the third trench is less than a width of the second trench.

9. The semiconductor device of claim 1, wherein at least a portion of the inner sidewall of the first trench between the two adjacent first recesses comprises a linear shape.

10. The semiconductor device of claim 1, wherein each of the first recesses and the second recesses comprises a nonlinear shape.

11. The semiconductor device of claim 1, wherein each of the inner sidewall of the first trench and the inner sidewall of the second trench comprises a nonlinear shape.

12. A semiconductor device comprising:
a substrate comprising a cell region, a core region, and a boundary region between the cell region and the core region, wherein the substrate comprises first active patterns spaced apart in a first horizontal direction and a second horizontal direction in the cell region, wherein the first horizontal direction is parallel with a top surface of the substrate, and wherein the second horizontal direction is parallel with the top surface of the substrate and perpendicular to the first horizontal direction;
a first trench and a second trench that are defined by the first active patterns; and
an isolation film in the first trench and the second trench,
wherein each of the first active patterns comprises a long axis in a third horizontal direction that is parallel with the top surface of the substrate and intersects the first horizontal direction and the second horizontal direction,
the first trench is between a first adjacent pair of first active patterns in the second horizontal direction from among the first active patterns,
the second trench is between a second adjacent pair of first active patterns in the third horizontal direction from among the first active patterns,
a width of the second trench is greater than a width of the first trench, and
a bottom of the first trench and a bottom of the second trench extend from the substrate by a substantially equal distance.

13. The semiconductor device of claim 12, wherein:
an inner sidewall of the first trench comprises first recesses that extend into a first one of the first active patterns, wherein the first one of the active patterns is adjacent to the first trench, and wherein the first recesses are spaced apart from each other in a vertical direction that intersects the top surface of the substrate,
an inner sidewall of the second trench comprises second recesses that extend into a second one of the first active patterns, wherein the second one of the first active patterns is adjacent to the second trench, and wherein the second recesses are spaced from each other in the vertical direction,
a distance between two adjacent first recesses from among the first recesses in the vertical direction corresponds to a first height,
a distance between two adjacent second recesses from among the second recesses in the vertical direction corresponds to a second height, and
the first height is substantially equal to the second height.

14. The semiconductor device of claim 13, further comprising:
a third trench that is defined by a second active pattern, wherein the second active pattern is in the boundary region,
an inner sidewall of the third trench comprises third recesses that extend into the second active pattern, wherein the third recesses are spaced apart from each other in the vertical direction,
a distance between two adjacent third recesses from among the third recesses in the vertical direction corresponds to a third height, and
the third height is greater than at least one of the first height and the second height.

15. The semiconductor device of claim 14, wherein:
the inner sidewall of the third trench further comprises fourth recesses that extend into the second active pattern, wherein the fourth recesses are below the third recesses and are spaced apart from each other in the vertical direction,
a distance between two adjacent fourth recesses from among the fourth recesses in the vertical direction corresponds to a fourth height, and
the fourth height is different from the third height.

16. The semiconductor device of claim 15, wherein the fourth height is less than the third height.

17. The semiconductor device of claim 16, wherein the fourth height is substantially equal to each of the first height and the second height.

18. The semiconductor device of claim 15, further comprising:
a fourth trench that is in the boundary region and between one of the first active patterns and the second active pattern,
wherein an inner sidewall of the fourth trench comprises fifth recesses and sixth recesses that are below the fifth recesses, wherein the fifth recesses and the sixth recesses extend into the second active pattern, wherein the fifth recesses and the sixth recesses are respectively spaced apart from each another in the vertical direction,
a distance between two adjacent fifth recesses from among the fifth recesses in the vertical direction corresponds to a fifth height,
a distance between two adjacent sixth recesses from among the sixth recesses in the vertical direction corresponds to a sixth height,
the fifth height is substantially equal to the third height, and
the sixth height is substantially equal to the fourth height.

19. A semiconductor device comprising:
a substrate that comprises a cell region, a core region, and a boundary region between the cell region and the core region, wherein the substrate comprises a first active pattern in the cell region and a second active pattern in the core region, wherein the first active pattern comprises a long axis in a first horizontal direction, a first source/drain region, and a second source/drain region that is spaced apart from the first source/drain region in the first horizontal direction;
a first trench that is defined by the first active pattern, wherein an inner sidewall of the first trench comprises first recesses that extend into the first active pattern;
a second trench that is defined by the second active pattern, wherein an inner sidewall of the second trench comprises second recesses that extend into the second active pattern;
an isolation film in the first trench and the second trench;
a gate electrode in a groove between the first and second source/drain regions of the first active pattern, wherein the gate electrode extends in a second horizontal direction;
a line structure that extends on the first active pattern in a third horizontal direction that intersects the second horizontal direction, wherein the line structure extends from the cell region to the boundary region and comprises a first conductive pattern, a bit line on the first conductive pattern, and a first barrier pattern between the bit line and the first conductive pattern, and wherein the first conductive pattern is electrically connected to the first source/drain region;
a core gate structure on the second active pattern, wherein the core gate structure comprises a second conductive pattern corresponding to the first conductive pattern, a second barrier pattern corresponding to the first barrier pattern, and a core gate electrode corresponding to the bit line; and
a sidewall spacer on a sidewall of the core gate structure,
wherein a distance between two adjacent first recesses from among the first recesses in a vertical direction that intersects a top surface of the substrate is less than a distance between two adjacent second recesses from among the second recesses in the vertical direction.

20. The semiconductor device of claim 19, wherein each of the first recesses and the second recesses comprises a nonlinear shape.
